(19) United States
(12) Patent Application Publication
(10) Pub. No.: US 2024/0413161 A1
(43) Pub. Date: Dec. 12, 2024

(54) SEMICONDUCTOR DEVICE

(71) Applicant: SAMSUNG ELECTRONICS CO., LTD., Suwon-si (KR)

(72) Inventors: Ho-Jun Kim, Suwon-si (KR); Hyeonwoo Lee, Suwon-si (KR)

(21) Appl. No.: 18/414,223

(22) Filed: Jan. 16, 2024

(30) Foreign Application Priority Data
Jun. 8, 2023 (KR) 10-2023-0073823

(51) Int. Cl. H01L 27/118

(52) U.S. Cl. CPC H01L 27/11807; H01L 2027/11831; H01L 2027/11853; H01L 2027/11881

(57) ABSTRACT

A semiconductor device may include a substrate including an active pattern, a device isolation layer defining the active pattern, a channel pattern on the active pattern, a gate electrode on the channel pattern, and a first isolation pattern and a second isolation pattern penetrating the gate electrode. The first isolation pattern may be extended into the device isolation layer, and the second isolation pattern may be provided to penetrate the gate electrode and the device isolation layer and may be extended into an upper portion of the substrate. A level of a bottom surface of the second isolation pattern may be lower than a level of a bottom surface of the device isolation layer.

### CROSS-REFERENCE TO RELATED APPLICATIONS

This U.S. non-provisional patent application claims priority under 35 U.S.C. § 119 to Korean Patent Application No. 10-2023-0073823, filed on Jun. 8, 2023, in the Korean Intellectual Property Office, the entire content of which is hereby incorporated by reference.

### TECHNICAL FIELD

The present disclosure relates to a semiconductor device, and in particular, to a semiconductor device including a field effect transistor.

### BACKGROUND

A semiconductor device includes an integrated circuit composed of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize the semiconductor devices with high performance.

### SUMMARY

An implementation of the present disclosure provides a semiconductor device with improved reliability.

An implementation of the present disclosure provides a semiconductor device with improved electric characteristics.

According to an implementation of the present disclosure, a semiconductor device may include a substrate including an active pattern, a device isolation layer defining the active pattern, a channel pattern on the active pattern, a gate electrode on the channel pattern, and a first isolation pattern and a second isolation pattern penetrating the gate electrode. The first isolation pattern may be extended into the device isolation layer, and the second isolation pattern may be provided to penetrate the gate electrode and the device isolation layer and may be extended into an upper portion of the substrate. A level of a bottom surface of the second isolation pattern may be lower than a level of a bottom surface of the device isolation layer.

According to an implementation of the present disclosure, a semiconductor device may include a substrate, a device isolation layer filling a trench on the substrate, a first isolation pattern on the device isolation layer, an active contact on the first isolation pattern, and a lower power line provided below the substrate. The lower power line may include an interconnection portion and a contact portion protruding from the interconnection portion toward the substrate. The contact portion may be provided to penetrate the substrate, the device isolation layer, and the first isolation pattern and may be electrically connected to the active contact.

According to an implementation of the present disclosure, a semiconductor device may include a first gate electrode, a second gate electrode, and a third gate electrode provided on a substrate, extended in a first direction, and sequentially arranged in a second direction crossing the first direction, source/drain patterns provided respectively between the first to third gate electrodes, and an isolation structure penetrating the first to third gate electrodes. The isolation structure may include a first isolation pattern extended in the second direction to divide the first gate electrode into a pair of gate electrodes, which are spaced apart from each other in the first direction, a second isolation pattern extended in the first direction to penetrate the second gate electrode, a third isolation pattern extended in the first direction to penetrate the third gate electrode, a first void on a first region where the first and second isolation patterns intersect each other, and a second void on a second region where the first and third isolation patterns intersect each other. When viewed in a plan view, the first void may be a cross-shaped region with four curved surfaces, and the second void may be a T-shaped region with two curved surfaces.

### BRIEF DESCRIPTION OF THE DRAWINGS

FIGS. 1 to 3 are conceptual diagrams illustrating logic cells of a semiconductor device according to an implementation of the present disclosure.

FIG. 4 is a plan view illustrating a semiconductor device according to an implementation of the present disclosure.

FIGS. 5A to 5G are sectional views taken along lines A-A′, B-B′, C-C′, D-D′, E-E′, F-F′, and G-G′ of FIG. 4.

FIGS. 6A to 6C are sectional views, taken along the lines C-C′, F-F′, and G-G′ of FIG. 4, respectively, and illustrate a semiconductor device according to an implementation of the present disclosure.

FIG. 7A is an enlarged plan view illustrating a portion (e.g., M of FIG. 4) of a semiconductor device according to an implementation of the present disclosure.

FIG. 7B is an enlarged plan view illustrating a semiconductor device according to another implementation of the present disclosure.

FIGS. 8A and 8B are sectional views taken along lines I-I′ and II-II′ of FIG. 7A.

FIGS. 9A, 9B, 9C, 10A, 10B, 10C, 11A, 11B, 11C, 12A, 12B, 12C, 13A, 13B, 13C, 13D, 14A, 14B, 14C, 14D, 15A, 15B, 15C, 15D, 16A, 16B, 16C, 16D, 16E, 16F, 16G, 17A, 17B, 17C, 17D, 17E, 17F, 17G, 18A, 18B, 18C, 18D, 18E, 18F, 18G, 19A, 19B, 19C, 19D, 19E, 19F, 19G, 20A, 20B, 20C, 20D, 20E, 20F, and 20G are sectional views illustrating a method of fabricating a semiconductor device, according to an implementation of the present disclosure.

### DETAILED DESCRIPTION

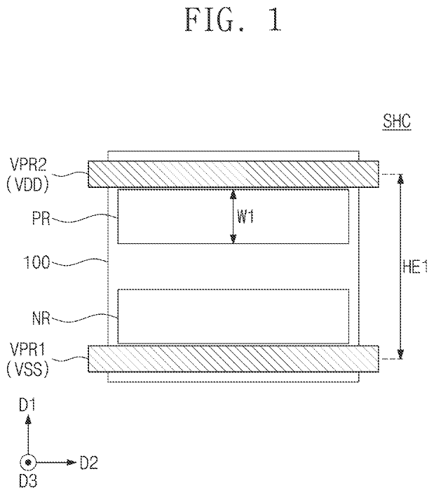

FIGS. 1 to 3 are conceptual diagrams illustrating logic cells of a semiconductor device according to an implementation of the present disclosure.

Referring to FIG. 1, a single height cell SHC may be provided. In detail, a first lower power line VPR1 and a second lower power line VPR2 may be provided in a lower portion of a substrate 100. The first lower power line VPR1 may be a conduction path, to which a source voltage VSS (e.g., a ground voltage) is provided. The second lower power line VPR2 may be a conduction path, to which a drain voltage VDD (e.g., a power voltage) is provided.

The single height cell SHC may be defined between the first lower power line VPR1 and the second lower power line VPR2. The single height cell SHC may include one PMOSFET region PR and one NMOSFET region NR. In other words, the single height cell SHC may have a CMOS structure provided between the first lower power line VPR1 and the second lower power line VPR2.

Each of the PMOSFET and NMOSFET regions PR and NR may have a width W1 in a first direction D1. A length of the single height cell SHC in the first direction D1 may be defined as a first height HE1. The first height HE1 may be substantially equal to a distance (e.g., pitch) between the first lower power line VPR1 and the second lower power line VPR2.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

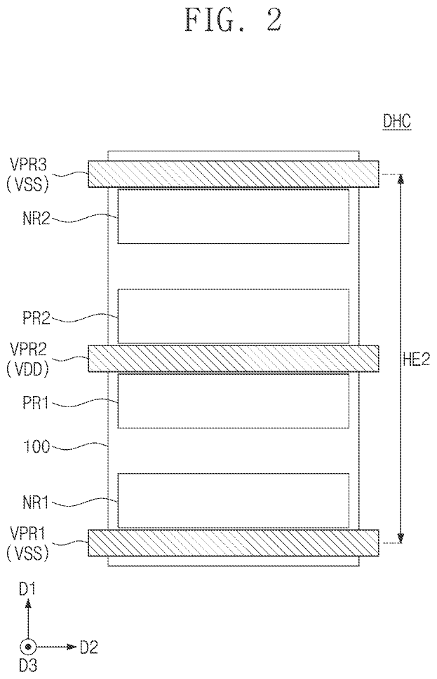

Referring to FIG. 2, a double height cell DHC may be provided. In detail, the first lower power line VPR1, the second lower power line VPR2, and a third lower power line VPR3 may be provided on the substrate 100. The second lower power line VPR2 may be disposed between the first lower power line VPR1 and the third lower power line VPR3. The third lower power line VPR3 may be a conduction path, to which the source voltage VSS is provided.

The double height cell DHC may be defined between the first lower power line VPR1 and the third lower power line VPR3. The double height cell DHC may include a first PMOSFET region PR1, a second PMOSFET region PR2, a first NMOSFET region NR1, and a second NMOSFET region NR2.

The first NMOSFET region NR1 may be adjacent to the first lower power line VPR1. The second NMOSFET region NR2 may be adjacent to the third lower power line VPR3. The first and second PMOSFET regions PR1 and PR2 may be adjacent to the second lower power line VPR2. When viewed in a plan view, the second lower power line VPR2 may be disposed between the first and second PMOSFET regions PR1 and PR2.

A length of the double height cell DHC in the first direction D1 may be defined as a second height HE2. The second height HE2 may be about two times the first height HE1 of FIG. 1. The first and second PMOSFET regions PR1 and PR2 of the double height cell DHC may be combined to serve as a single PMOSFET region. Thus, a channel size of the PMOS transistor of the double height cell DHC may be larger than a channel size of the PMOS transistor of the single height cell SHC of FIG. 1.

For example, the channel size of the PMOS transistor of the double height cell DHC may be about two times the channel size of the PMOS transistor of the single height cell SHC. In this case, the double height cell DHC may be operated at a higher speed than the single height cell SHC. In an implementation, the double height cell DHC shown in FIG. 2 may be defined as a multi-height cell. Although not shown, the multi-height cell may include a triple height cell whose cell height is about three times that of the single height cell SHC.

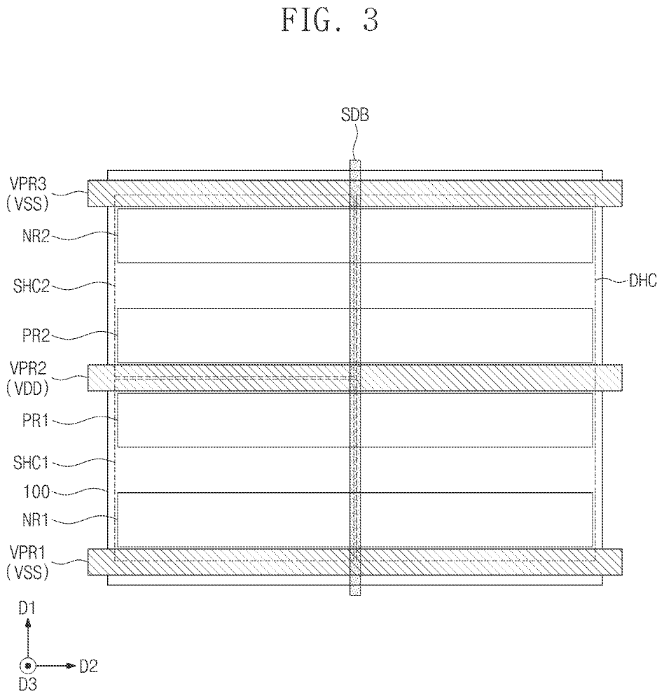

Referring to FIG. 3, a first single height cell SHC1, a second single height cell SHC2, and a double height cell DHC may be two-dimensionally arranged on the substrate 100. The first single height cell SHC1 may be disposed between the first and second lower power lines VPR1 and VPR2. The second single height cell SHC2 may be disposed between the second and third lower power lines VPR2 and VPR3. The second single height cell SHC2 may be adjacent to the first single height cell SHC1 in the first direction D1.

The double height cell DHC may be disposed between the first and third lower power lines VPR1 and VPR3. The double height cell DHC may be adjacent to the first and second single height cells SHC1 and SHC2 in a second direction D2.

A division structure pattern SDB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure pattern SDB.

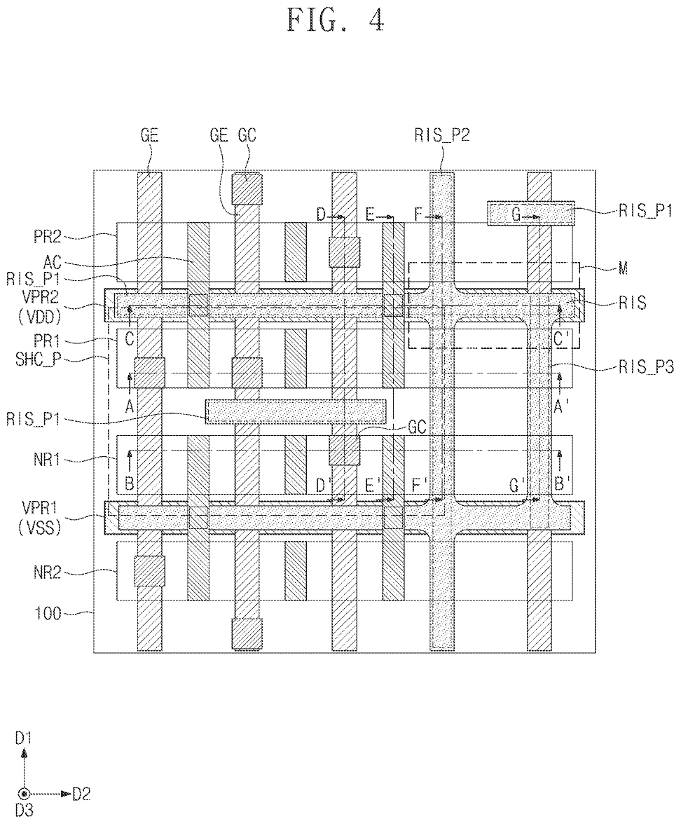

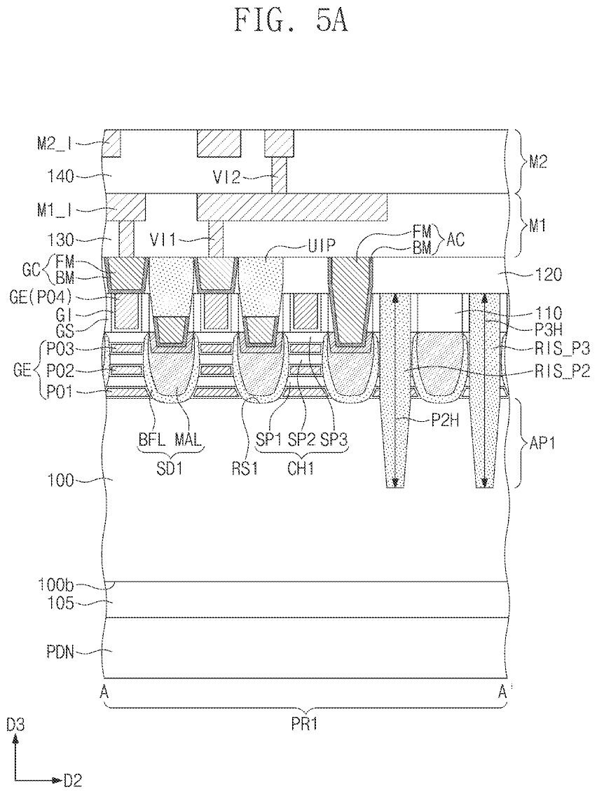

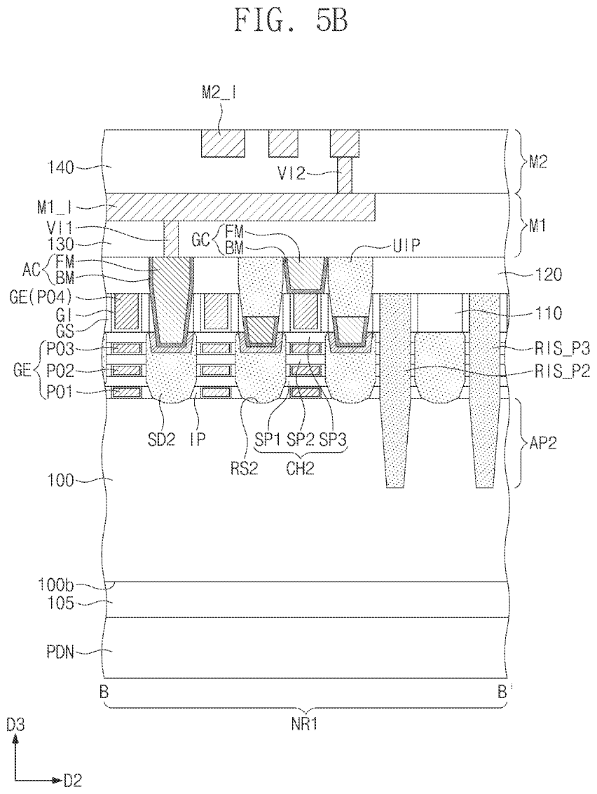

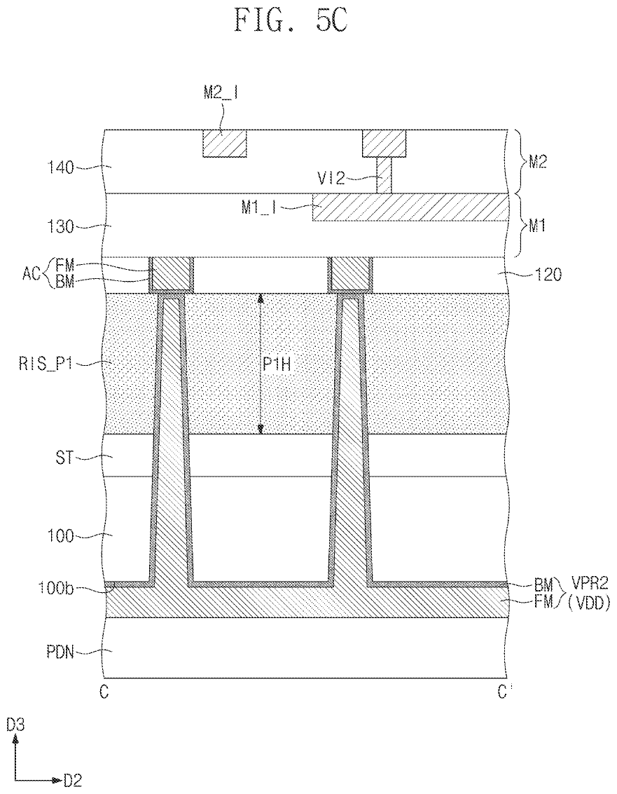

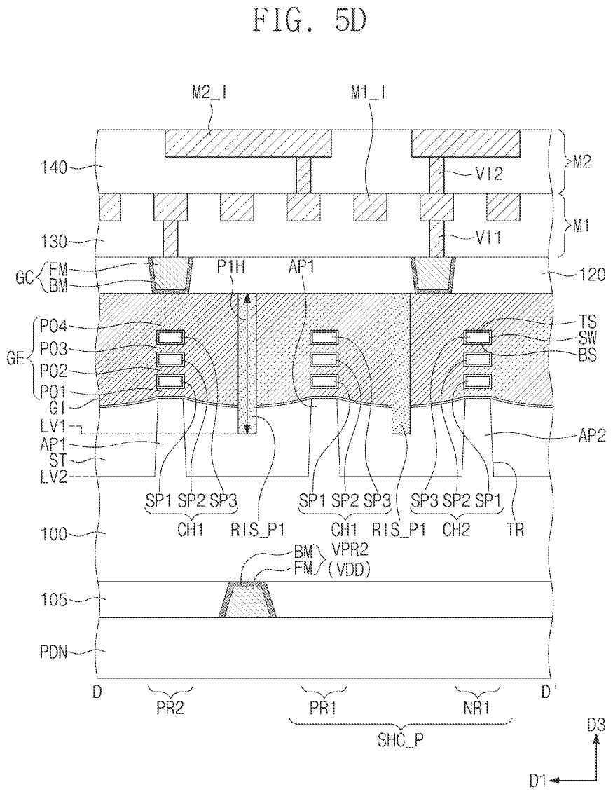

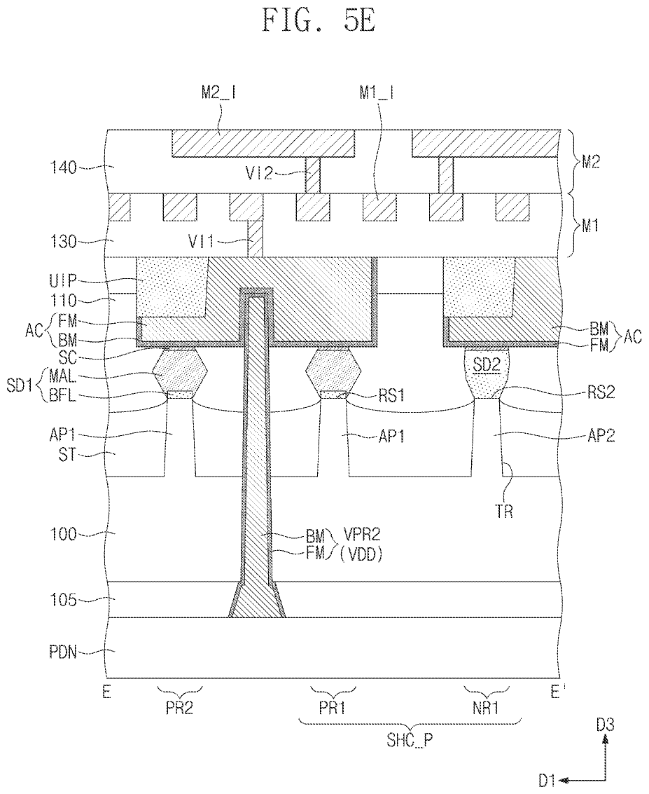

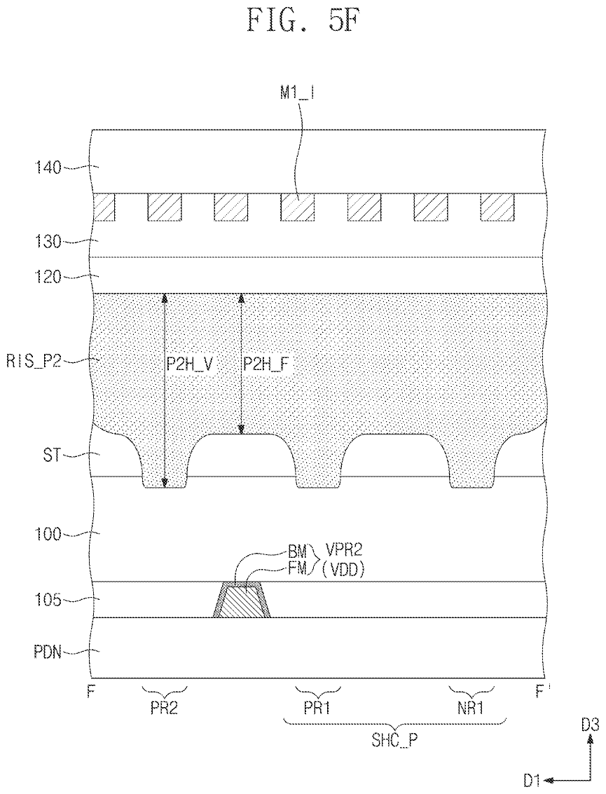

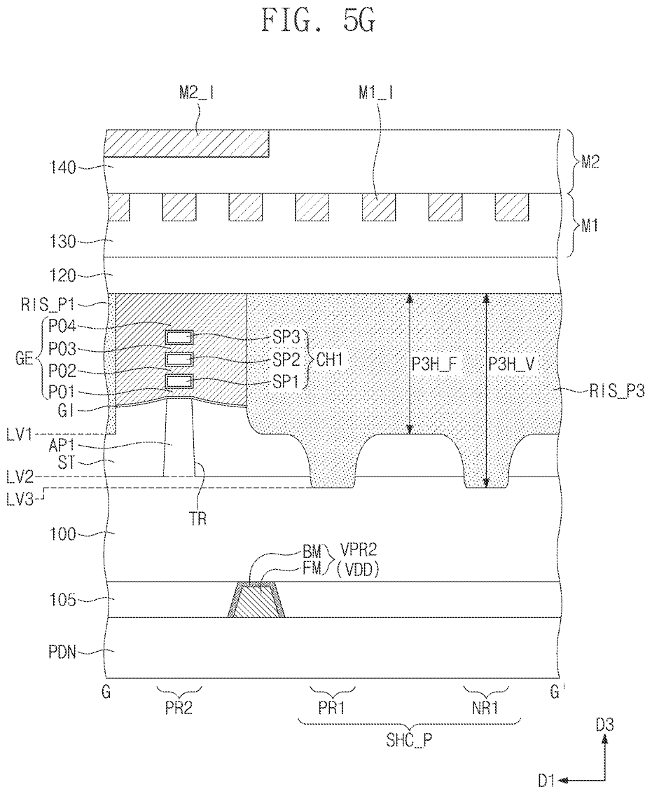

FIG. 4 is a plan view illustrating a semiconductor device according to an implementation of the present disclosure. FIGS. 5A to 5G are sectional views taken along lines A-A′, B-B′, C-C′, D-D′, E-E′, F-F′, and G-G′ of FIG. 4. FIGS. 4 and 5A to 5G illustrate an example of a detailed structure of the first and second single height cells SHC1 and SHC2 of FIG. 3.

Referring to FIGS. 4 and 5A to 5G, an edge cell SHC_P may be provided on the substrate 100. Logic transistors constituting a logic circuit may be disposed on the edge cell SHC_P. The substrate 100 may be a semiconductor substrate that is formed of or includes silicon, germanium, silicon germanium, a compound semiconductor material, or the like. In an implementation, the substrate 100 may be a silicon wafer.

The substrate 100 may include the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may be extended in the second direction D2. The edge cell SHC_P may include the first NMOSFET region NR1 and the first PMOSFET region PR1.

A first active pattern AP1 and a second active pattern AP2 may be defined by a trench TR, which is formed in an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may be extended in the second direction D2. Each of the first and second active patterns AP1 and AP2 may be a vertically-protruding portion of the substrate 100.

A device isolation layer ST may be provided on the substrate 100. The device isolation layer ST may be provided to fill the trench TR. The device isolation layer ST may be formed of or include silicon oxide. The device isolation layer ST may not cover first and second channel patterns CH1 and CH2 to be described below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (i.e., a third direction D3).

Each of the first to third semiconductor patterns SP1, SP2, and SP3 may be formed of or include silicon (Si), germanium (Ge), or silicon germanium (SiGe). For example, each of the first to third semiconductor patterns SP1, SP2, and SP3 may be formed of or include crystalline silicon.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., n-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., p-type). The second channel pattern CH2 may be interposed between each pair of the second source/drain patterns SD2. In other words, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. In an implementation, each of the first and second source/drain patterns SD1 and SD2 may have a top surface that is higher than a top surface of the third semiconductor pattern SP3. In another implementation, a top surface of at least one of the first and second source/drain patterns SD1 and SD2 may be located at substantially the same level as the top surface of the third semiconductor pattern SP3.

The first source/drain patterns SD1 may include a semiconductor material (e.g., SiGe) whose lattice constant is greater than that of the substrate 100. In this case, the pair of the first source/drain patterns SD1 may exert a compressive stress on the first channel patterns CH1 therebetween. The second source/drain patterns SD2 may be formed of or include the same semiconductor material (e.g., Si) as the substrate 100.

Each of the first source/drain patterns SD1 may include a buffer layer BFL and a main layer MAL on the buffer layer BFL. Referring back to FIG. 5A, the buffer layer BFL may cover an inner surface the first recess RS1. In an implementation, the buffer layer BFL may have a substantially conformal thickness. For example, a thickness of the buffer layer BFL, which is measured in the third direction D3 on a bottom of the first recess RS1, may be substantially equal to a thickness of the buffer layer BFL, which is measured in the second direction D2 at a top level of the first recess RS1.

In an implementation, the buffer layer BFL may have a decreasing thickness in an upward direction. For example, the thickness of the buffer layer BFL, which is measured in the third direction D3 on the bottom of the first recess RS1, may be larger than a thickness of the buffer layer BFL, which is measured in the second direction D2 at the top level of the first recess RS1. In addition, the buffer layer BFL may have a ‘U’-shaped section corresponding to a profile of the first recess RS1.

The main layer MAL may fill most of an unfilled region of the first recess RS1 covered with the buffer layer BFL. The main layer MAL may have a volume that is greater than that of the buffer layer BFL. Each of the buffer and main layers BFL and MAL may be formed of or include silicon germanium (SiGe). In detail, the buffer layer BFL may contain a relatively low concentration of germanium (Ge). In another implementation, the buffer layer BFL may contain only silicon (Si), without germanium (Ge). A germanium concentration of the buffer layer BFL may range from 0 at % to 10 at %.

The main layer MAL may contain a relatively high concentration of germanium. In an implementation, the germanium concentration of the main layer MAL may range from 30 at % to 70 at %. The germanium concentration of the main layer MAL may increase in the third direction D3. For example, a portion of the main layer MAL, which is adjacent to the buffer layer BFL, may have a germanium concentration of about 40 at %, and an upper portion of the main layer MAL may have a germanium concentration of about 60 at %.

Each of the buffer and main layers BFL and MAL may contain an impurity (e.g., boron, gallium, or indium) that allows the first source/drain pattern SD1 to have a p-type conductivity. The impurity concentration of each of the buffer and main layers BFL and MAL may range from 1.0×10¹⁸ atom/cm³ to 5.0×10²² atom/cm³. The impurity concentration of the main layer MAL may be higher than the impurity concentration of the buffer layer BFL.

The buffer layer BFL may prevent a stacking fault between the substrate 100 (i.e., the first active pattern AP1) and the main layer MAL and between the first to third semiconductor patterns SP1, SP2, and SP3 and the main layer MAL. The stacking fault may lead to an increase of a channel resistance. The buffer layer BFL may protect the main layer MAL in a process of replacing second semiconductor layers SAL with first to third portions PO1, PO2, and PO3 of a gate electrode GE, as will be described below. In other words, the buffer layer BFL may prevent an etchant material, which is used to remove the second semiconductor layers SAL, from entering and etching the main layer MAL.

Each of the second source/drain patterns SD2 may be formed of or include silicon (Si). The second source/drain pattern SD2 may further contain impurities (e.g., phosphorus, arsenic, or antimony) that allow the second source/drain pattern SD2 to have an n-type conductivity. An impurity concentration of the second source/drain pattern SD2 may range from 1.0×10¹⁸ atom/cm³ to 5.0×10²² atom/cm³.

Gate electrodes GE may be provided to extend in the first direction D1 and cross the first and second channel patterns CH1 and CH2. The gate electrodes GE may be arranged at a first pitch in the second direction D2. Each of the gate electrodes GE may be vertically overlapped with the first and second channel patterns CH1 and CH2.

The gate electrode GE may include a first portion PO1 interposed between the active pattern AP1 or AP2 and the first semiconductor pattern SP1, a second portion PO2 interposed between the first and second semiconductor patterns SP1 and SP2, a third portion PO3 interposed between the second and third semiconductor patterns SP2 and SP3, and a fourth portion PO4 on the third semiconductor pattern SP3.

Referring back to FIG. 5D, the gate electrode GE may be provided on a top surface TS, a bottom surface BS, and opposite side surfaces SW of each of the first to third semiconductor patterns SP1, SP2, and SP3. That is, the transistor according to the present implementation may be a three-dimensional field effect transistor (e.g., MBCFET or GAAFET) in which the gate electrode GE is provided to three-dimensionally surround the channel pattern.

A first isolation pattern RIS_P1 of an isolation structure RIS may be provided on a border of the edge cell SHC_P. The first isolation pattern RIS_P1 may be overlapped with the gate electrodes GE, respectively. The first isolation pattern RIS_P1 may be formed of or include an insulating material (e.g., silicon oxide, silicon nitride, silicon oxynitride, or combinations thereof).

The gate electrode GE on the edge cell SHC_P may be separated from the gate electrode GE, which is placed on the single height cell around the edge cell SHC_P, by the first isolation pattern RIS_P1. That is, the gate electrode GE, which is extended in the first direction D1, may be divided into a plurality of the gate electrodes GE by the first isolation pattern RIS_P1. The first isolation pattern RIS_P1 will be described in more detail below.

Referring back to FIGS. 4 and 5A to 5G, a pair of gate spacers GS may be respectively disposed on opposite side surfaces of the fourth portion PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. The gate spacers GS may be formed of or include at least one of SiCN, SiCON, or SiN. In an implementation, the gate spacers GS may be a multi-layered structure, which includes at least two different materials selected from SiCN, SiCON, and SiN.

Although not shown, a gate capping pattern may be provided on the gate electrode GE. The gate capping pattern may be extended along the gate electrode GE and in the first direction D1. The gate capping pattern may be formed of or include a material having an etch selectivity with respect to first and second interlayer insulating layers 110 and 120, which will be described below. In detail, the gate capping pattern may be formed of or include at least one of SiON, SiCN, SiCON, or SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and opposite side surfaces SW1 and SW2 of each of the first to third semiconductor patterns SP1, SP2, and SP3. The gate insulating layer GI may cover a top surface of the device isolation layer ST below the gate electrode GE.

In an implementation, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In another implementation, the semiconductor device may include a negative capacitance (NC) FET using a negative capacitor. For example, the gate insulating layer GI may include a ferroelectric layer exhibiting a ferroelectric property and a paraelectric layer exhibiting a paraelectric property.

The ferroelectric layer may have a negative capacitance, and the paraelectric layer may have a positive capacitance. In the case where two or more capacitors are connected in series and each capacitor has a positive capacitance, a total capacitance may be reduced to a value that is less than a capacitance of each of the capacitors. By contrast, in the case where at least one of serially-connected capacitors has a negative capacitance, a total capacitance of the serially-connected capacitors may have a positive value and may be greater than an absolute value of each capacitance.

In the case where a ferroelectric layer having a negative capacitance and a paraelectric layer having a positive capacitance are connected in series, a total capacitance of the serially-connected ferroelectric and paraelectric layers may be increased. Due to such an increase of the total capacitance, a transistor including the ferroelectric layer may have a subthreshold swing (SS), which is less than 60 mV/decade, at the room temperature.

The ferroelectric layer may have the ferroelectric property. The ferroelectric layer may be formed of or include at least one of, for example, hafnium oxide, hafnium zirconium oxide, barium strontium titanium oxide, barium titanium oxide, and/or lead zirconium titanium oxide. Here, the hafnium zirconium oxide may be hafnium oxide that is doped with zirconium (Zr). Alternatively, the hafnium zirconium oxide may be a compound composed of hafnium (Hf), zirconium (Zr), and/or oxygen (O).

The ferroelectric layer may further include dopants. For example, the dopants may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The kind of the dopants in the ferroelectric layer may vary depending on a ferroelectric material included in the ferroelectric layer.

In the case where the ferroelectric layer includes hafnium oxide, the dopants in the ferroelectric layer may include at least one of, for example, gadolinium (Gd), silicon (Si), zirconium (Zr), aluminum (Al), and/or yttrium (Y).

In the case where the dopants are aluminum (Al), a content of aluminum in the ferroelectric layer may range from 3 to 8 at % (atomic percentage). Here, the content of the dopants (e.g., aluminum atoms) may be a ratio of the number of aluminum atoms to the number of hafnium and aluminum atoms.

In the case where the dopants are silicon (Si), a content of silicon in the ferroelectric layer may range from 2 at % to 10 at %. In the case where the dopants are yttrium (Y), a content of yttrium in the ferroelectric layer may range from 2 at % to 10 at %. In the case where the dopants are gadolinium (Gd), a content of gadolinium in the ferroelectric layer may range from 1 at % to 7 at %. In the case where the dopants are zirconium (Zr), a content of zirconium in the ferroelectric layer may range from 50 at % to 80 at %.

The paraelectric layer may have the paraelectric property. The paraelectric layer may be formed of or include at least one of, for example, silicon oxide and/or high-k metal oxides. The metal oxides, which can be used as the paraelectric layer, may include at least one of, for example, hafnium oxide, zirconium oxide, and/or aluminum oxide, but the present disclosure is not limited to these examples.

The ferroelectric layer and the paraelectric layer may be formed of or include the same material. The ferroelectric layer may have the ferroelectric property, but the paraelectric layer may not have the ferroelectric property. For example, in the case where the ferroelectric and paraelectric layers contain hafnium oxide, a crystal structure of the hafnium oxide in the ferroelectric layer may be different from a crystal structure of the hafnium oxide in the paraelectric layer.

The ferroelectric layer may exhibit the ferroelectric property, only when its thickness is in a specific range. In an implementation, the ferroelectric layer may have a thickness ranging from 0.5 to 10 nm, but the present disclosure is not limited to this example. Since a critical thickness associated with the occurrence of the ferroelectric property varies depending on the kind of the ferroelectric material, the thickness of the ferroelectric layer may be changed depending on the kind of the ferroelectric material.

As an example, the gate insulating layer GI may include a single ferroelectric layer. As another example, the gate insulating layer GI may include a plurality of ferroelectric layers spaced apart from each other. The gate insulating layer GI may have a multi-layered structure, in which a plurality of ferroelectric layers and a plurality of paraelectric layers are alternately stacked.

The gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third portions PO1, PO2, and PO3 of the gate electrode GE may be composed of the first metal pattern or the work-function metal.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In an implementation, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may include at least one metallic material, which is selected from the group consisting of tungsten (W), aluminum (Al), titanium (Ti), and tantalum (Ta). For example, the fourth portion PO4 of the gate electrode GE may include the first metal pattern and the second metal pattern on the first metal pattern.

Referring back to FIG. 5B, inner spacers IP may be provided on the first and second NMOSFET regions NR1 and NR2. In other words, the inner spacers IP may be provided on the second active pattern AP2. The inner spacers IP may be respectively interposed between the first to third portions PO1, PO2, and PO3 of the gate electrode GE and the second source/drain pattern SD2. The inner spacers IP may be in direct contact with the second source/drain pattern SD2. Each of the first to third portions PO1, PO2, and PO3 of the gate electrode GE may be spaced apart from the second source/drain pattern SD2 by the inner spacer IP.

A first interlayer insulating layer 110 may be provided on the substrate 100. The first interlayer insulating layer 110 may cover the gate spacers GS and the first and second source/drain patterns SD1 and SD2. A top surface of the first interlayer insulating layer 110 may be substantially coplanar with the top surface of the gate electrode GE and the top surface of the gate spacer GS. Although not shown, the top surface of the first interlayer insulating layer 110 may be substantially coplanar with a top surface of the gate capping pattern and the top surface of the gate spacer GS. A second interlayer insulating layer 120 may be disposed on the first interlayer insulating layer 110. A third interlayer insulating layer 130 may be provided on the second interlayer insulating layer 120. A fourth interlayer insulating layer 140 may be provided on the third interlayer insulating layer 130. In an implementation, at least one of the first to fourth interlayer insulating layers 110 to 140 may include a silicon oxide layer.

The isolation structure RIS may include a second isolation pattern RIS_P2 and a third isolation pattern RIS_P3, which are provided at a side of the edge cell SHC_P and are extended in the second direction D2. For example, the second isolation pattern RIS_P2 may be provided on the border of the edge cell SHC_P. The third isolation pattern RIS_P3 may be spaced apart from the second isolation pattern RIS_P2 with the first and second source/drain patterns SD1 and SD2 interposed therebetween.

The second and third isolation patterns RIS_P2 and RIS_P3 may be extended in the first direction D1 to be parallel to the gate electrodes GE. A pitch between the second isolation pattern RIS_P2 and the gate electrode GE, which are adjacent to each other, or a pitch between the second isolation pattern RIS_P2 and the third isolation pattern RIS_P3 may be equal to the first pitch. The second and third isolation patterns RIS_P2 and RIS_P3 may be formed of or include an insulating material (e.g., silicon oxide, silicon nitride, silicon oxynitride, or combinations thereof).

The second and third isolation patterns RIS_P2 and RIS_P3 may be provided to penetrate the gate electrode GE and may be extended into the first and second active patterns AP1 and AP2. The second and third isolation patterns RIS_P2 and RIS_P3 may be provided to penetrate the first and second active patterns AP1 and AP2 and may be extended into an upper portion of the substrate 100. Each of the second and third isolation patterns RIS_P2 and RIS_P3 may electrically separate an active region of each of the single height cells from an active region of a neighboring cell. The second and third isolation patterns RIS_P2 and RIS_P3 will be described in more detail below.

Active contacts AC may be provided to penetrate the first and second interlayer insulating layers 110 and 120 and to be electrically connected to the first and second source/drain patterns SD1 and SD2, respectively. A pair of the active contacts AC may be respectively provided at both sides of the gate electrode GE. When viewed in a plan view, the active contact AC may be a bar-shaped pattern that is extended in the first direction D1.

The active contact AC may be a self-aligned contact. In other words, the active contact AC may be formed by a self-alignment process using the gate spacer GS. For example, the active contact AC may cover at least a portion of the side surface of the gate spacer GS. Although not shown, the active contact AC may be provided to cover a portion of the top surface of the gate capping pattern.

Metal-semiconductor compound layers SC (e.g., silicide layers) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, or cobalt silicide.

Gate contacts GC may be provided to penetrate the second interlayer insulating layer 120 and may be electrically connected to the gate electrodes GE, respectively. When viewed in a plan view, two gate contacts GC on the edge cell SHC_P may be disposed on and overlapped with the first PMOSFET region PR1. In other words, the two gate contacts GC on the edge cell SHC_P may be provided on the first active pattern AP1 (e.g., see FIG. 5A). When viewed in a plan view, one gate contact GC on the edge cell SHC_P may be disposed and overlapped with the first NMOSFET region NR1. In other words, the gate contact GC on the edge cell SHC_P may be provided on the second active pattern AP2 (e.g., see FIG. 5B).

The gate contact GC may be freely disposed on the gate electrode GE, without any restrictions on its position. For example, the gate contacts GC may be respectively disposed on the second PMOSFET region PR2, the second NMOSFET region NR2, and the device isolation layer ST filling the trench TR (e.g., see FIG. 4).

In an implementation, referring to FIGS. 5A, 5B, and 5E an upper portion of the active contact AC adjacent to the gate contact GC may be filled with an upper insulating pattern UIP. A bottom surface of the upper insulating pattern UIP may be lower than a bottom surface of the gate contact GC. In other words, a top surface of the active contact AC adjacent to the gate contact GC may be formed at a level, which is lower than the bottom surface of the gate contact GC, by the upper insulating pattern UIP. Accordingly, it may be possible to prevent the gate contact GC and the active contact AC, which are adjacent to each other, from being in contact with each other and thereby to prevent a short circuit issue from occurring therebetween.

Each of the active and gate contacts AC and GC may include a conductive pattern FM and a barrier pattern BM enclosing the conductive pattern FM. For example, the conductive pattern FM may be formed of or include at least one of metallic materials (e.g., aluminum, copper, tungsten, molybdenum, and cobalt). The barrier pattern BM may be provided to cover side and bottom surfaces of the conductive pattern FM. In an implementation, the barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

Referring back to FIGS. 4, 5C, and 5E, the first and second lower power lines VPR1 and VPR2 may be provided below the substrate 100. The first and second lower power lines VPR1 and VPR2 may be extended in the second direction D2 to be parallel to each other. The first and second lower power lines VPR1 and VPR2 may be disposed on the border of the edge cell SHC_P.

Referring back to FIGS. 5C and 5E, the second lower power line VPR2 may be electrically connected to at least one active contact AC. The second lower power line VPR2 may include an interconnection portion, which is a line-shaped pattern extended in the second direction D2, and a contact portion, which is extended from the interconnection portion to protrude in the third direction D3. In detail, the contact portion may be provided to penetrate the substrate 100, the device isolation layer ST, and the first isolation pattern RIS_P1 and to be in contact with the active contact AC. A width of the contact portion may decrease as the distance to the active contact AC decreases in the third direction D3. As a result, in the semiconductor device according to the present implementation, the lower power lines VPR1 and VPR2 may be electrically connected to the source/drain patterns SD1 and SD2 through the active contact AC.

The first and second lower power lines VPR1 and VPR2 may include the conductive pattern FM and the barrier pattern BM. For example, the conductive pattern THE FORMATION OF may be formed of or include at least one of metallic materials (e.g., aluminum, copper, tungsten, molybdenum, and cobalt). In an implementation, the barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

A bottom surface of the interconnection portion may be coplanar with a bottom surface 100b of the substrate 100. A power delivery network layer PDN may be provided on the bottom surface 100b of the substrate 100. The power delivery network layer PDN may include a plurality of lower interconnection lines that are electrically connected to the first and second lower power lines VPR1 and VPR2. As an example, the power delivery network layer PDN may include a wiring network, which is used to apply the source voltage VSS to the first lower power line VPR1. The power delivery network layer PDN may include a wiring network, which is used to apply the drain voltage VDD to the second lower power line VPR2.

A first metal layer M1 may be provided in the third interlayer insulating layer 130. The first metal layer M1 may include first interconnection lines M1_I. The first interconnection lines M1_I of the first metal layer M1 may be extended in the second direction D2 to be parallel to each other.

According to an implementation of the present disclosure, the lower power lines VPR1 and VPR2, which are disposed below the substrate 100, may be used as a power line of supplying an electric power to the single height cell. Thus, the power line may be omitted from the first metal layer M1. The first interconnection lines M1_I, which are used for signal transmission, may be disposed in the first metal layer M1. The first interconnection lines M1_I may be arranged at a second pitch in the first direction D1. The second pitch may be smaller than the first pitch.

The first metal layer M1 may further include first vias VI1. The first vias VI1 may be respectively provided below the first interconnection lines M1_I of the first metal layer M1. The first interconnection line M1_I of the first metal layer M1 may be electrically connected to the active contact AC through the first via VI1. The first interconnection line M1_I of the first metal layer M1 may be electrically connected to the gate contact GC through the first via VI1.

The first interconnection line M1_I of the first metal layer M1 and the first via VI1 thereunder may be separately formed by different processes. That is, each of the first interconnection line M1_I and the first via VI1 of the first metal layer M1 may be formed by a single damascene process. The semiconductor device according to the present implementation may be fabricated using a sub-20 nm process.

A second metal layer M2 may be provided in a fourth interlayer insulating layer 140. The second metal layer M2 may include a plurality of second interconnection lines M2_I. Each of the second interconnection lines M2_I of the second metal layer M2 may be a line- or bar-shaped pattern that is extended in the first direction D1. In other words, the second interconnection lines M2_I may be extended in the first direction D1 to be parallel to each other.

The second metal layer M2 may further include second vias VI2, which are respectively provided below the second interconnection lines M2_I. The first interconnection line M1_I of the first metal layer M1 and the second interconnection line M2_I of the second metal layer M2 may be electrically connected to each other through the second via VI2. In an implementation, the second interconnection line M2_I of the second metal layer M2 and the second via VI2 thereunder may be formed by a dual damascene process.

The first interconnection line M1_I of the first metal layer M1 and the second interconnection line M2_I of the second metal layer M2 may be formed of or include the same conductive material or different conductive materials. For example, the first interconnection line M1_I of the first metal layer M1 and the second interconnection line M2_I of the second metal layer M2 may be formed of or include at least one of metallic materials (e.g., aluminum, copper, tungsten, molybdenum, ruthenium, and cobalt). Although not shown, a plurality of metal layers (e.g., M3, M4, M5, and so forth) may be additionally stacked on the fourth interlayer insulating layer 140. Each of the stacked metal layers may include interconnection lines, which are used as routing paths between cells.

Referring back to FIGS. 4 and 5A to 5G, the isolation structure RIS may be provided on the border of the edge cell SHC_P. The isolation structure RIS may be provided to cut a plurality of the gate electrodes GE extending in the first direction D1. The isolation structure RIS may be provided to penetrate the gate electrode GE and active patterns AP1 and AP2. In other words, the isolation structure RIS may electrically separate an active region of the single height cell from an active region of a neighboring cell.

The isolation structure RIS may include the first isolation pattern RIS_P1, the second isolation pattern RIS_P2, and the third isolation pattern RIS_P3. The first isolation pattern RIS_P1 may be extended in the second direction D2. The first isolation pattern RIS_P1 may divide one gate electrode GE into a pair of the gate electrodes GE, which are spaced apart from each other in the first direction D1. The second and third isolation patterns RIS_P2 and RIS_P3 may be extended in the first direction D1. The second and third isolation patterns RIS_P2 and RIS_P3 may be provided to penetrate the gate electrode GE.

Referring to FIGS. 4, 5C, and 5D, the first isolation pattern RIS_P1 may be provided on the substrate 100 between the first and second PMOSFET regions PR1 and PR2, between the first and second NMOSFET regions NR1 and NR2, or between the first PMOSFET and NMOSFET regions PR1 and NR1.

The first isolation pattern RIS_P1 may be provided to penetrate the gate electrode GE and the gate insulating layer GI and may be extended to the device isolation layer ST. In detail, the first isolation pattern RIS_P1 may be extended into the device isolation layer ST. A level LV1 of a bottom surface of the first isolation pattern RIS_P1 may be higher than a level LV_ST of a bottom surface of the device isolation layer ST. A top surface of the first isolation pattern RIS_P1 may be substantially coplanar with the top surface of the gate electrode GE. In an implementation, the top surface of the first isolation pattern RIS_P1 may be higher than the top surface of the gate electrode GE. In other words, the top surface of the first isolation pattern RIS_P1 may be located at a level that is equal to or higher than the top surface of the gate electrode GE.

In an implementation, although not shown, the gate capping pattern may be provided on the gate electrode GE. The top surface of the first isolation pattern RIS_P1 may be located at the same level as the top surface of the gate capping pattern. The top surface of the first isolation pattern RIS_P1 may be located at a level higher than the top surface of the gate capping pattern.

The first isolation pattern RIS_P1 may be a single layer including at least one of silicon oxide, silicon nitride, or silicon oxynitride. That is, the first isolation pattern RIS_P1 may be a single layer including an insulating material. The first isolation pattern RIS_P1 may further include a void, which is formed near a top surface thereof. The void will be described in more detail below.

The first isolation pattern RIS_P1 may have a first height P1H. The first height P1H may be defined as a vertical distance from the bottom surface of the first isolation pattern RIS_P1 to the uppermost surface of the first isolation pattern RIS_P1. For example, the first height P1H may range from 90 nm to 130 nm.

Referring to FIGS. 4, 5A, 5B, 5F, and 5G, the second and third isolation patterns RIS_P2 and RIS_P3 may be provided on the first PMOSFET region PR1 or the first NMOSFET region NR1. The second and third isolation patterns RIS_P2 and RIS_P3 on the first PMOSFET region PR1 may be spaced apart from each other, with the first source/drain pattern SD1 interposed therebetween. The second and third isolation patterns RIS_P2 and RIS_P3 on the first NMOSFET region NR1 may be spaced apart from each other, with the second source/drain pattern SD2 interposed therebetween.

The second and third isolation patterns RIS_P2 and RIS_P3 may be provided to penetrate the gate electrode GE, the gate insulating layer GI, and the device isolation layer ST and may be extended to the substrate 100. In detail, the second and third isolation patterns RIS_P2 and RIS_P3 may be extended into an upper portion of the substrate 100. A level LV2 of a bottom surface of the second isolation pattern RIS_P2 may be lower than the level LV_ST of the bottom surface of the device isolation layer ST. A level LV3 of a bottom surface of the third isolation pattern RIS_P3 may be lower than the level LV_ST of the bottom surface of the device isolation layer ST.

A top surface of each of the second and third isolation patterns RIS_P2 and RIS_P3 may be substantially coplanar with the top surface of the gate electrode GE. In an implementation, the top surface of each of the second and third isolation patterns RIS_P2 and RIS_P3 may be higher than the top surface of the gate electrode GE. In other words, the top surface of each of the second and third isolation patterns RIS_P2 and RIS_P3 may be located at a level, which is equal to or higher than the top surface of the gate electrode GE.

In an implementation, although not shown, the gate capping pattern may be provided on the gate electrode GE. The top surface of each of the second and third isolation patterns RIS_P2 and RIS_P3 may be located at the same level as the top surface of the gate capping pattern. The top surface of each of the second and third isolation patterns RIS_P2 and RIS_P3 may be located at a level higher than the top surface of the gate capping pattern.

Each of the second and third isolation patterns RIS_P2 and RIS_P3 may be composed of a single layer including at least one of silicon oxide, silicon nitride, or silicon oxynitride. In other words, each of the second and third isolation patterns RIS_P2 and RIS_P3 may be a single layer including an insulating material. Each of the second and third isolation patterns RIS_P2 and RIS_P3 may further include a void, which is formed near a top surface thereof. The void will be described in more detail below.

The second isolation pattern RIS_P2 may have a second height P2H, and the third isolation pattern RIS_P3 may have a third height P3H. The second height P2H may be defined as a vertical distance from the bottom surface of the second isolation pattern RIS_P2 to the uppermost surface of the second isolation pattern RIS_P2. The third height P3H may be defined as a vertical distance from the bottom surface of the third isolation pattern RIS_P3 to the uppermost surface of the third isolation pattern RIS_P3. The second and third heights P2H and P3H may be equal to each other. For example, both the second and third heights P2H and P3H may range from 140 nm to 180 nm.

Referring back to FIG. 5F, the second isolation pattern RIS_P2 may include a first portion and a second portion. The first portion may be provided to penetrate the gate electrode GE and the gate insulating layer GI and may be extended into the device isolation layer ST. The first portion may have a first depth P2H_F. The first depth P2H_F may be defined as a vertical distance from the top surface of the device isolation layer ST to a bottom surface of the second interlayer insulating layer 120. The first depth P2H_F may be equal to the first height P1H of FIG. 5C. For example, the first depth P2H_F may range from 90 nm to 130 nm.

The second portion may be provided to penetrate the gate electrode GE, the gate insulating layer GI, and the active pattern and may be extended into an upper portion of the substrate 100. The second portion may have a second depth P2H_V. The second depth P2H_V may be defined as a vertical distance from the lowermost surface of the second isolation pattern RIS_P2 to the bottom surface of the second interlayer insulating layer 120. The second depth P2H_V may be equal to the second height P2H of FIG. 5A. For example, the second depth P2H_V may range from 140 nm to 180 nm.

Referring back to FIG. 5G, the third isolation pattern RIS_P3 may include a third portion and a fourth portion. The third portion may be provided to penetrate the gate electrode GE and the gate insulating layer GI and may be extended into the device isolation layer ST. The third portion may have a third depth P3H_F. The third depth P3H_F may be defined as a vertical distance from the top surface of the device isolation layer ST to the bottom surface of the second interlayer insulating layer 120. The third depth P3H_F may be equal to the first height P1H of FIG. 5C. For example, the third depth P3H_F may range from 90 nm to 130 nm.

The fourth portion may be provided to penetrate the gate electrode GE, the gate insulating layer GI, and the active pattern AP1 or AP2 and may be extended into an upper portion of the substrate 100. The fourth portion may have a fourth depth P3H_V. The fourth depth P3H_V may be defined as a vertical distance from the lowermost surface of the third isolation pattern RIS_P3 to the bottom surface of the second interlayer insulating layer 120. The fourth depth P3H_V may be equal to the third height P3H of FIG. 5A. For example, the fourth depth P3H_V may range from 140 nm to 180 nm.

In other words, the second isolation pattern RIS_P2 may include the first and second portions having different vertical lengths from each other, and the third isolation pattern RIS_P3 may include the third and fourth portions having different vertical lengths from each other. This may be because there may be a difference in etch rate or etch selectivity between the device isolation layer ST and the active patterns AP1 and AP2, under an etching gas or etchant material that is used in a subsequent etching process of the fabrication process.

The level LV1 of the bottom surface of the first isolation pattern RIS_P1 may be higher than the level LV_ST of the bottom surface of the device isolation layer ST, and the level LV3 of the bottom surface of the third isolation pattern RIS_P3 may be lower than the level LV_ST of the bottom surface of the device isolation layer ST. In other words, the level LV_ST of the bottom surface of the device isolation layer ST may be placed between the level LV1 of the bottom surface of the first isolation pattern RIS_P1 and the level LV3 of the bottom surface of the third isolation pattern RIS_P3.

In an implementation, the afore-described structure of the isolation structure RIS may be formed simultaneously. In other words, the first to third isolation patterns RIS_P1, RIS_P2, and RIS_P3 of the isolation structure RIS may be formed as a single object. Since the first to third isolation patterns RIS_P1, RIS_P2, and RIS_P3 are formed at the same time, the first height P1H of FIG. 5C, the first depth P2H_F of FIG. 5F, and the third depth P3H_F of FIG. 5G may be substantially equal to each other. In addition, it may be possible to reduce the number of photomasks, which are used to form the first to third isolation patterns RIS_P1, RIS_P2, and RIS_P3 as a single object, and thereby to reduce a fabrication cost of the semiconductor device. As a result, it may be possible to improve the efficiency in the fabrication process of a semiconductor device and the reliability of the semiconductor device.

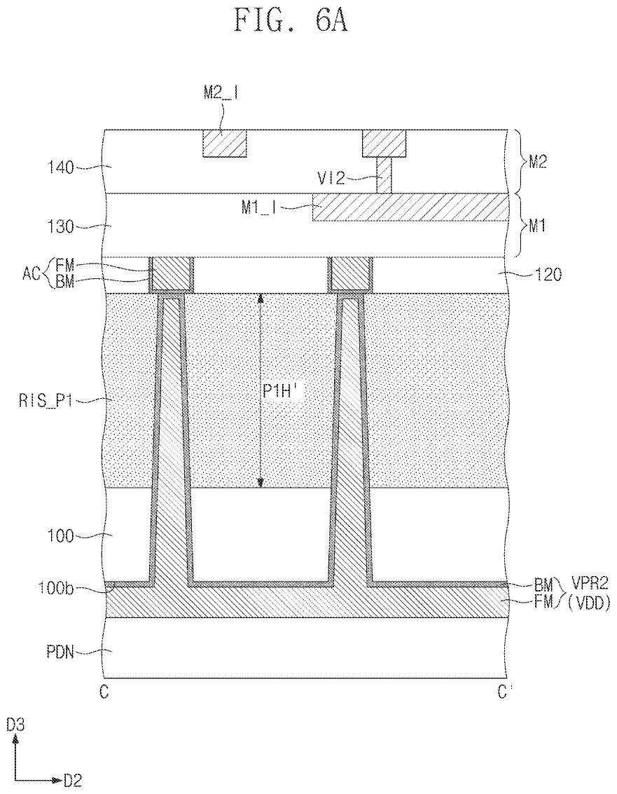

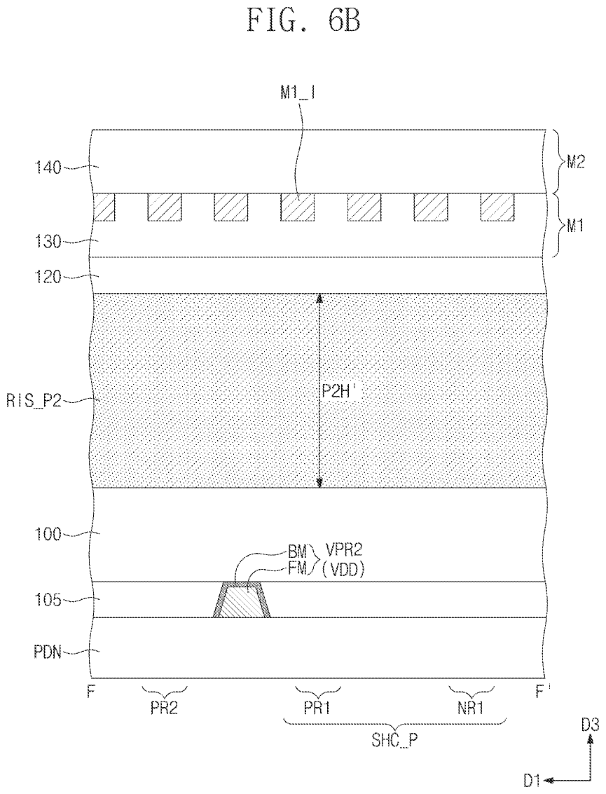

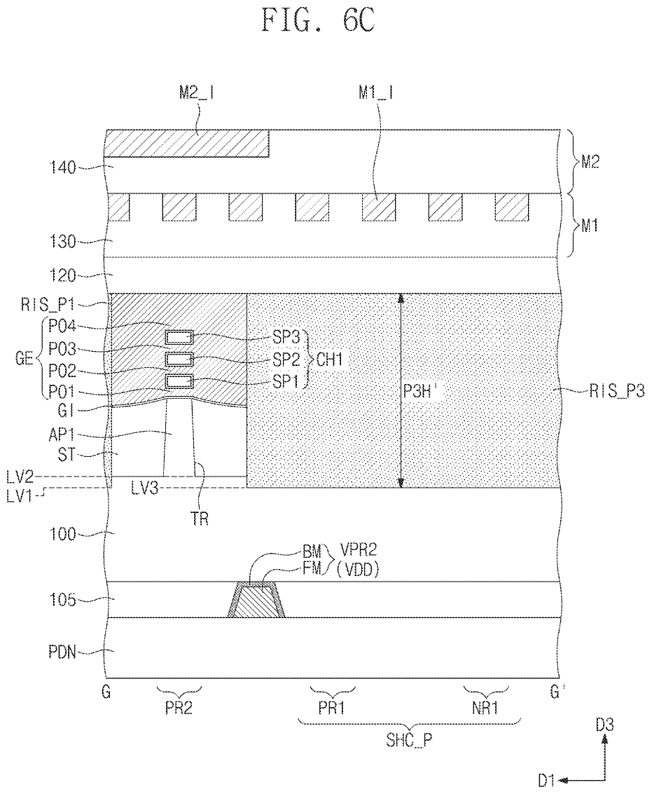

Hereinafter, various implementations of the present disclosure will be described. In the following description of these implementations, an element previously described with reference to FIGS. 4 and 5A to 5G may be identified by the same reference number without repeating an overlapping description thereof, for concise description. FIGS. 6A to 6C are sectional views illustrating a semiconductor device according to an implementation of the present disclosure. FIGS. 6A, 6B, and 6C are sectional views, which are respectively taken along the lines C-C′, F-F′, and G-G′ of FIG. 4.

Referring to FIGS. 6A to 6C, the first isolation pattern RIS_P1 may have a fourth height P1H′. The fourth height P1H′ may be defined as a vertical distance from the bottom surface of the first isolation pattern RIS_P1 to the uppermost surface of the first isolation pattern RIS_P1. In other words, the first isolation pattern RIS_P1 may be provided to penetrate the gate electrode GE, the gate insulating layer GI, and the device isolation layer ST and may be extended to an upper portion of the substrate 100.

The second isolation pattern RIS_P2 may have a fifth height P2H′. The fifth height P2H′ may be defined as a vertical distance from the bottom surface of the second isolation pattern RIS_P2 to the uppermost surface of the second isolation pattern RIS_P2. The bottom surface of the second isolation pattern RIS_P2 may be located at the same level as the bottom surface of the first isolation pattern RIS_P1.

The third isolation pattern RIS_P3 may have a sixth height P3H′. The sixth height P3H′ may be defined as a vertical distance from the bottom surface of the third isolation pattern RIS_P3 to the uppermost surface of the third isolation pattern RIS_P3. The bottom surface of the third isolation pattern RIS_P3 may be located at the same level as the bottom surface of the first isolation pattern RIS_P1 and the bottom surface of the second isolation pattern RIS_P2.

A top surface of each of the first, second, and third isolation patterns RIS_P1, RIS_P2, and RIS_P3 may be substantially coplanar with the top surface of the gate electrode GE. In an implementation, the top surface of each of the first, second, and third isolation patterns RIS_P1, RIS_P2, and RIS_P3 may be higher than the top surface of the gate electrode GE. Since the first to third isolation patterns RIS_P1, RIS_P2, and RIS_P3 have the top surfaces at the same level and the bottom surfaces at the same level, the fourth height P1H′, the fifth height P2H′, and the sixth height P3H′ may be equal to each other.

Referring back to FIG. 6C, the level LV1 of the bottom surface of the first isolation pattern RIS_P1 may be equal to the level LV3 of the bottom surface of the third isolation pattern RIS_P3. The level LV1 of the bottom surface of the first isolation pattern RIS_P1 and the level LV3 of the bottom surface of the third isolation pattern RIS_P3 may be lower than the level LV_ST of the bottom surface of the device isolation layer ST. In other words, the bottom surface of the first isolation pattern RIS_P1 and the bottom surface of the third isolation pattern RIS_P3 may be located at a level lower than the bottom surface of the device isolation layer ST. Since the bottom surface of the second isolation pattern RIS_P2 is placed at the same level as the bottom surface of the first isolation pattern RIS_P1 and the bottom surface of the third isolation pattern RIS_P3, the level of the bottom surface of the second isolation pattern RIS_P2 may be lower than the level LV_ST of the bottom surface of the device isolation layer ST.

According to an implementation of the present disclosure, an etchant material, which is used to etch a metallic material in the gate electrode GE, may be chosen to etch silicon oxide or silicon with the same etch selectivity. In this case, the device isolation layer ST and the active patterns AP1 and AP2 may be uniformly etched, and thus, the first to third isolation patterns RIS_P1, RIS_P2, and RIS_P3 may have the same vertical length. In other words, the fourth height P1H′, the fifth height P2H′, and the sixth height P3H′ may be equal to each other.

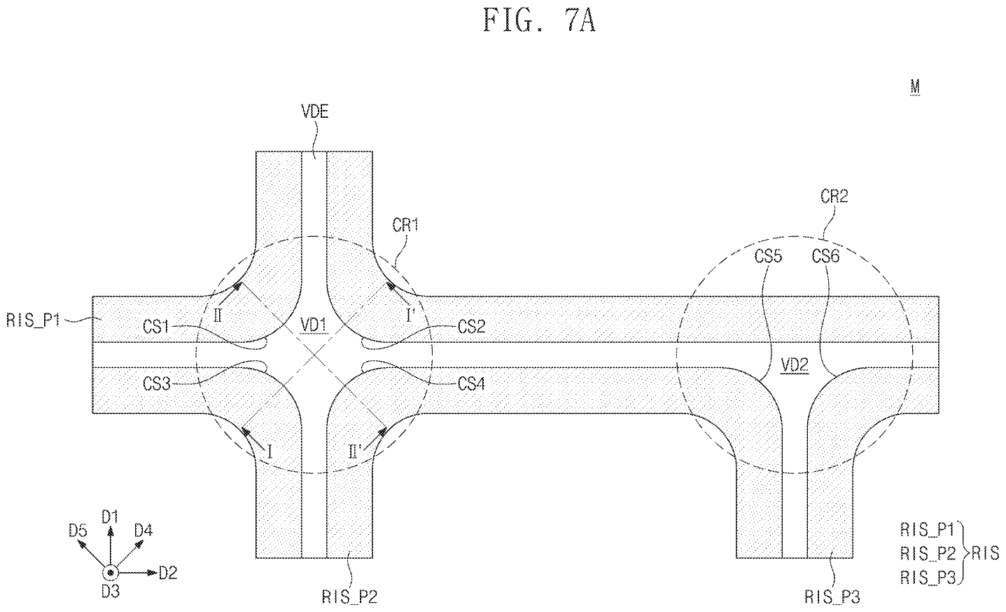

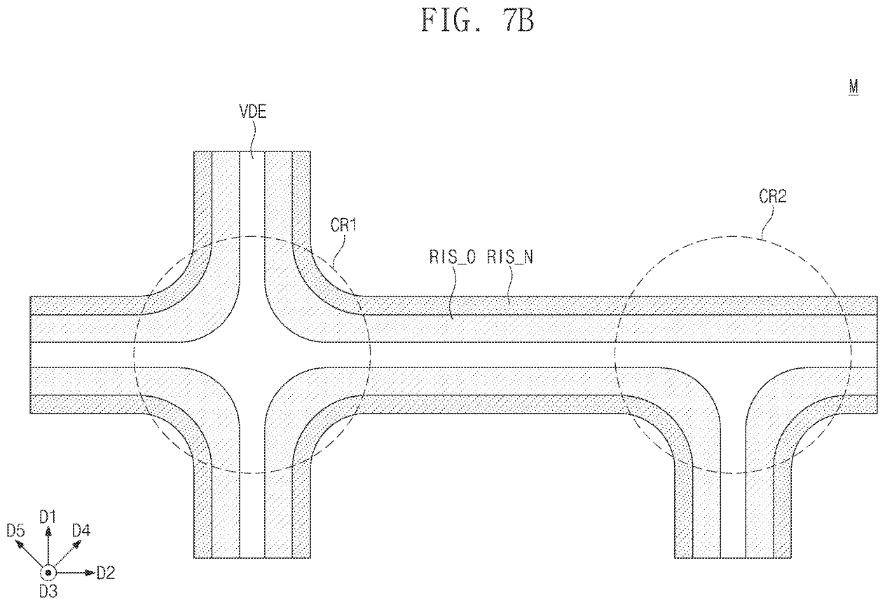

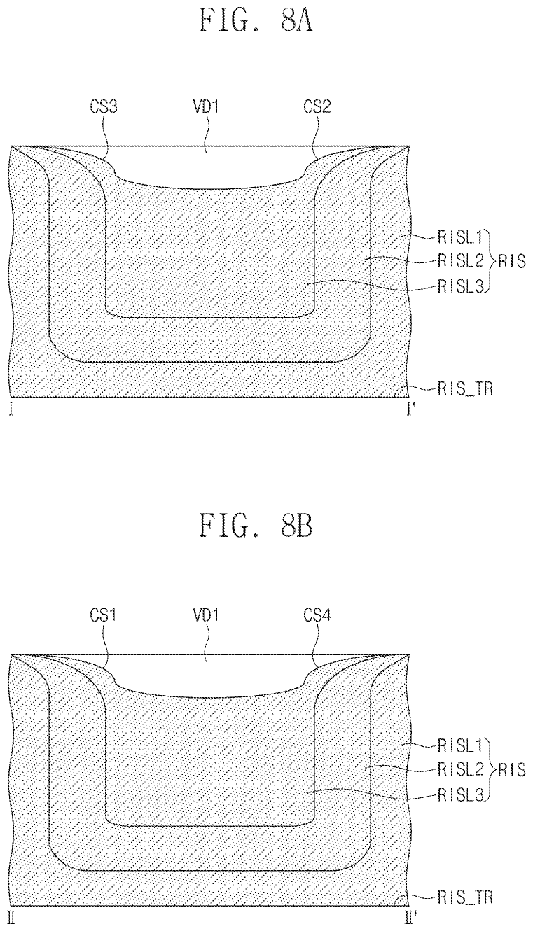

In the following description, an element previously described with reference to FIGS. 4, 5A to 5G, and 6A to 6C may be identified by the same reference number without repeating an overlapping description thereof, for concise description. FIG. 7A is an enlarged plan view illustrating a portion (e.g., M of FIG. 4) of a semiconductor device according to an implementation of the present disclosure, and FIG. 7B is an enlarged plan view illustrating a semiconductor device according to another implementation of the present disclosure. FIGS. 8A and 8B are sectional views taken along lines I-I′ and II-II′ of FIG. 7A.

Referring to FIGS. 4 and 7A, a plurality of the gate electrodes GE may be provided on the substrate 100 to extent in the first direction D1. The gate electrodes GE may be sequentially arranged in the second direction D2. The gate electrodes GE, which are sequentially arranged, may include a first gate electrode, a second gate electrode, and a third gate electrode.

Source/drain patterns may be respectively provided between the first to third gate electrodes. The source/drain patterns may be provided on the first and second PMOSFET regions PR1 and PR2 and the first and second NMOSFET regions NR1 and NR2.

The isolation structure RIS may include the first isolation pattern RIS_P1, which is extended in the second direction D2, and the second and third isolation patterns RIS_P2 and RIS_P3, which are extended in the first direction D1. In detail, the first isolation patterns RIS_P1, which are spaced apart from each other in the first direction D1, and the second and third isolation patterns RIS_P2 and RIS_P3, which are spaced apart from each other in the second direction D2, may have a closed-loop shape or closed-ring shape, when viewed in a plan view.

The isolation structure RIS may be provided to penetrate the first to third gate electrodes. In detail, the first isolation pattern RIS_P1 may be provided to penetrate the first gate electrode and divide each of the first gate electrode into a pair of gate electrodes, which are spaced apart from each other in the first direction D1. The second isolation pattern RIS_P2 may be provided to penetrate the second gate electrode, and the third isolation pattern RIS_P3 may be provided to penetrate the third gate electrode. For example, the second isolation pattern RIS_P2 may be provided to penetrate the entirety of the second gate electrode, and the third isolation pattern RIS_P3 may be provided to penetrate a portion of the third gate electrode.

Referring back to FIG. 7A, the isolation structure RIS may include a first region CR1, where the first and second isolation patterns RIS_P1 and RIS_P2 intersect each other, and a second region CR2, where the first and third isolation patterns RIS_P1 and RIS_P3 intersect each other. The isolation structure RIS may further include a void portion VDE adjacent to a top surface thereof. The void portion VDE may include a first void VD1 on the first region CR1 and a second void VD2 on the second region CR2.

The first void VD1 may be a cross-shaped empty region including four curved surfaces CS1-CS4, when viewed in a plan view. The second void VD2 may be a T-shaped empty region including two curved surfaces CS5 and CS6, when viewed in a plan view.

FIGS. 8A and 8B are sectional views taken along lines I-I′ and II-II′ of FIG. 7A. As shown in FIG. 7A, the lines I-I′ and II-II′ are selected to be parallel to fourth and fifth directions D4 and D5, respectively. The fourth direction D4 may be defined to cross both the first and second directions D1 and D2. The fifth direction D5 may be defined to be orthogonal to the fourth direction D4.

Referring to FIGS. 8A and 8B, the isolation structure RIS may be a single layer, which is deposited by a chemical vapor deposition (CVD) process. The single layer may include a first isolation layer RISL1, which is extended from a bottom surface of an isolation trench RIS_TR to a side surface thereof, a second isolation layer RISL2 on the first isolation layer RISL1, and a third isolation layer RISL3 on the second isolation layer RISL2. The single layer may be a layer that is formed by sequentially depositing the first isolation layer RISL1, the second isolation layer RISL2, and the third isolation layer RISL3.

In the single layer of the semiconductor device according to an implementation of the present disclosure, there may be no observable interface between the first isolation layer RISL1 and the second isolation layer RISL2 and/or between the second isolation layer RISL2 and the third isolation layer RISL3. In other words, the isolation structure RIS may be a single layer, in which the first to third isolation layers RISL1, RISL2, and RISL3 are connected to each other without any observable interface.

The first void VD1 may be adjacent to a top surface of the isolation structure RIS. The first void VD1 may be enclosed by a second curved surface CS2 and a third curved surface CS3, which are opposite to each other in the fourth direction D4, and a first curved surface CS1 and a fourth curved surface CS4, which are opposite to each other in the fifth direction D5. In an implementation, the first void VD1 may have a hemispherical shape, which is recessed in a downward direction.

Referring back to FIG. 7B, the isolation structure RIS may be a double layer, which is deposited by a chemical vapor deposition (CVD) process. In detail, each of the first to third isolation patterns RIS_P1, RIS_P2, and RIS_P3 (e.g., of FIG. 7A) may be formed of or include a first sub-isolation pattern RIS_N and a second sub-isolation pattern RIS_O on the first sub-isolation pattern RIS_N. The first sub-isolation pattern RIS_N may be formed of or include silicon nitride or silicon oxynitride. The second sub-isolation pattern RIS_O may be formed of or include silicon oxide.

The isolation structure RIS may include the first region CR1, where the first and second isolation patterns RIS_P1 and RIS_P2 of FIG. 7A intersect each other, and the second region CR2, where the first and third isolation patterns RIS_P1 and RIS_P3 of FIG. 7A intersect each other. The isolation structure RIS may further include the void portion VDE adjacent to a top surface thereof. In detail, the void portion VDE may be interposed between the second sub-isolation patterns RIS_O. The void portion VDE may include the first void, which is placed on the first region CR1 and has a cross-shaped form, and the second void VD2, which is placed on the second region CR2 and has a T-shaped form.

Hereinafter, various implementations of the present disclosure will be described. In the following description of these implementations, an element previously described with reference to FIGS. 4 and 5A to 5G may be identified by the same reference number without repeating an overlapping description thereof, for concise description. FIGS. 6A to 6C are sectional views illustrating a semiconductor device according to an implementation of the present disclosure. FIGS. 6A, 6B, and 6C are sectional views, which are respectively taken along the lines C-C′, F-F′, and G-G′ of FIG. 4.

Referring to FIGS. 6A to 6C, the first isolation pattern RIS_P1 may have the fourth height P1H′. The fourth height P1H′ may be defined as a vertical distance from the bottom surface of the first isolation pattern RIS_P1 to the uppermost surface of the first isolation pattern RIS_P1. In other words, the first isolation pattern RIS_P1 may be provided to penetrate the gate electrode GE, the gate insulating layer GI, and the device isolation layer ST and may be extended to an upper portion of the substrate 100.

The second isolation pattern RIS_P2 may have the fifth height P2H′. The fifth height P2H′ may be defined as a vertical distance from the bottom surface of the second isolation pattern RIS_P2 to the uppermost surface of the second isolation pattern RIS_P2. The bottom surface of the second isolation pattern RIS_P2 may be located at the same level as the bottom surface of the first isolation pattern RIS_P1.

The third isolation pattern RIS_P3 may have the sixth height P3H′. The sixth height P3H′ may be defined as a vertical distance from the bottom surface of the third isolation pattern RIS_P3 to the uppermost surface of the third isolation pattern RIS_P3. The bottom surface of the third isolation pattern RIS_P3 may be located at the same level as the bottom surface of the first isolation pattern RIS_P1 and the bottom surface of the second isolation pattern RIS_P2.

A top surface of each of the first, second, and third isolation patterns RIS_P1, RIS_P2, and RIS_P3 may be substantially coplanar with the top surface of the gate electrode GE. In an implementation, the top surface of each of the first, second, and third isolation patterns RIS_P1, RIS_P2, and RIS_P3 may be higher than the top surface of the gate electrode GE. Since the first to third isolation patterns RIS_P1, RIS_P2, and RIS_P3 have the top surfaces at the same level and the bottom surfaces at the same level, the fourth height P1H′, the fifth height P2H′, and the sixth height P3H′ may be equal to each other.

Referring back to FIG. 6C, the level LV1 of the bottom surface of the first isolation pattern RIS_P1 may be equal to the level LV3 of the bottom surface of the third isolation pattern RIS_P3. The level LV1 of the bottom surface of the first isolation pattern RIS_P1 and the level LV3 of the bottom surface of the third isolation pattern RIS_P3 may be lower than the level LV_ST of the bottom surface of the device isolation layer ST. In other words, the bottom surface of the first isolation pattern RIS_P1 and the bottom surface of the third isolation pattern RIS_P3 may be located at a level lower than the bottom surface of the device isolation layer ST. Since the bottom surface of the second isolation pattern RIS_P2 is placed at the same level as the bottom surface of the first isolation pattern RIS_P1 and the bottom surface of the third isolation pattern RIS_P3, the level of the bottom surface of the second isolation pattern RIS_P2 may be lower than the level LV_ST of the bottom surface of the device isolation layer ST.

According to an implementation of the present disclosure, an etchant material, which is used to etch a metallic material in the gate electrode GE, may be chosen to etch silicon oxide or silicon with the same etch selectivity. In this case, the device isolation layer ST and the active patterns AP1 and AP2 may be uniformly etched, and thus, the first to third isolation patterns RIS_P1, RIS_P2, and RIS_P3 may have the same vertical length. In other words, the fourth height P1H′, the fifth height P2H′, and the sixth height P3H′ may be equal to each other.

In the following description, an element previously described with reference to FIGS. 4, 5A to 5G, and 6A to 6C may be identified by the same reference number without repeating an overlapping description thereof, for concise description. FIG. 7A is an enlarged plan view illustrating a portion (e.g., M of FIG. 4) of a semiconductor device according to an implementation of the present disclosure, and FIG. 7B is an enlarged plan view illustrating a semiconductor device according to another implementation of the present disclosure. FIGS. 8A and 8B are sectional views taken along lines I-I′ and II-II′ of FIG. 7A.

Referring to FIGS. 4 and 7A, a plurality of the gate electrodes GE may be provided on the substrate 100 to extent in the first direction D1. The gate electrodes GE may be sequentially arranged in the second direction D2. The gate electrodes GE, which are sequentially arranged, may include a first gate electrode, a second gate electrode, and a third gate electrode.

The source/drain patterns may be respectively provided between the first to third gate electrodes. The source/drain patterns may be provided on the first and second PMOSFET regions PR1 and PR2 and the first and second NMOSFET regions NR1 and NR2.

The isolation structure RIS may include the first isolation pattern RIS_P1, which is extended in the second direction D2, and the second and third isolation patterns RIS_P2 and RIS_P3, which are extended in the first direction D1. In detail, the first isolation patterns RIS_P1, which are spaced apart from each other in the first direction D1, and the second and third isolation patterns RIS_P2 and RIS_P3, which are spaced apart from each other in the second direction D2, may be connected to each other to have a closed-loop shape or closed-ring shape, when viewed in a plan view.

The isolation structure RIS may be provided to penetrate the first to third gate electrodes. In detail, the first isolation pattern RIS_P1 may be provided to penetrate the first gate electrode and divide each of the first gate electrode into a pair of gate electrodes, which are spaced apart from each other in the first direction D1. The second isolation pattern RIS_P2 may be provided to penetrate the second gate electrode, and the third isolation pattern RIS_P3 may be provided to penetrate the third gate electrode. For example, the second isolation pattern RIS_P2 may be provided to penetrate the entirety of the second gate electrode, and the third isolation pattern RIS_P3 may be provided to penetrate a portion of the third gate electrode.

Referring back to FIG. 7A, the isolation structure RIS may include the first region CR1, where the first and second isolation patterns RIS_P1 and RIS_P2 intersect each other, and the second region CR2, where the first and third isolation patterns RIS_P1 and RIS_P3 intersect each other. The isolation structure RIS may further include the void portion VDE adjacent to a top surface thereof. The void portion VDE may include the first void VD1 on the first region CR1 and the second void VD2 on the second region CR2.

The first void VD1 may be a cross-shaped empty region including four curved surfaces CS1-CS4, when viewed in a plan view. The second void VD2 may be a T-shaped empty region including two curved surfaces CS5 and CS6, when viewed in a plan view.

FIGS. 8A and 8B are sectional views taken along lines I-I′ and II-II′ of FIG. 7A. As shown in FIG. 7A, the lines I-I′ and II-II′ are selected to be parallel to the fourth and fifth directions D4 and D5, respectively. The fourth direction D4 may be defined to cross both the first and second directions D1 and D2. The fifth direction D5 may be defined to be orthogonal to the fourth direction D4.

Referring to FIGS. 8A and 8B, the isolation structure RIS may be a single layer, which is deposited by a chemical vapor deposition (CVD) process. The single layer may include the first isolation layer RISL1, which is extended from a bottom surface of the isolation trench RIS_TR to a side surface thereof, the second isolation layer RISL2 on the first isolation layer RISL1, and the third isolation layer RISL3 on the second isolation layer RISL2. The single layer may be a layer that is formed by sequentially depositing the first isolation layer RISL1, the second isolation layer RISL2, and the third isolation layer RISL3.

In the single layer of the semiconductor device according to an implementation of the present disclosure, there may be no observable interface between the first isolation layer RISL1 and the second isolation layer RISL2 and/or between the second isolation layer RISL2 and the third isolation layer RISL3. In other words, the isolation structure RIS may be a single layer, in which the first to third isolation layers RISL1, RISL2, and RISL3 are connected to each other without any observable interface.

The first void VD1 may be adjacent to the top surface of the isolation structure RIS. The first void VD1 may be enclosed by the second curved surface CS2 and the third curved surface CS3, which are opposite to each other in the fourth direction D4, and the first curved surface CS1 and the fourth curved surface CS4, which are opposite to each other in the fifth direction D5. In an implementation, the first void VD1 may have a hemispherical shape, which is recessed in a downward direction.

Referring back to FIG. 7B, the isolation structure RIS may be a double layer, which is deposited by a chemical vapor deposition (CVD) process. In detail, each of the first to third isolation patterns RIS_P1, RIS_P2, and RIS_P3 of FIG. 7A may include the first sub-isolation pattern RIS_N and the second sub-isolation pattern RIS_O on the first sub-isolation pattern RIS_N. The first sub-isolation pattern RIS_N may be formed of or include silicon nitride or silicon oxynitride. The second sub-isolation pattern RIS_O may be formed of or include silicon oxide.

The isolation structure RIS may include the first region CR1, where the first and second isolation patterns RIS_P1 and RIS_P2 of FIG. 7A intersect each other, and the second region CR2, where the first and third isolation patterns RIS_P1 and RIS_P3 of FIG. 7A intersect each other. The isolation structure RIS may further include the void portion VDE adjacent to a top surface thereof. In detail, the void portion VDE may be interposed between the second sub-isolation patterns RIS_O. The void portion VDE may include the first void, which is placed on the first region CR1 and has a cross-shaped form, and the second void VD2, which is placed on the second region CR2 and has a T-shaped form.

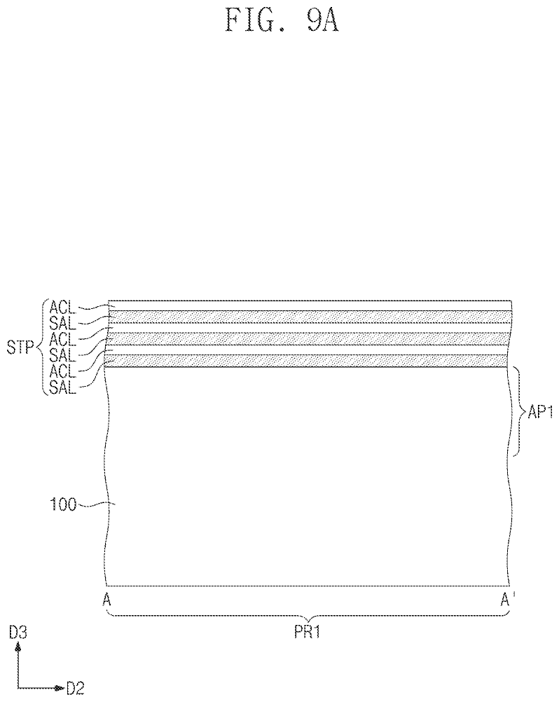

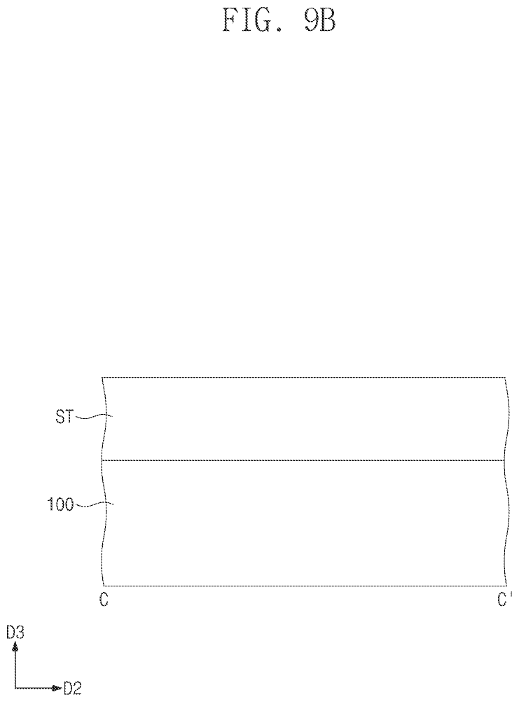

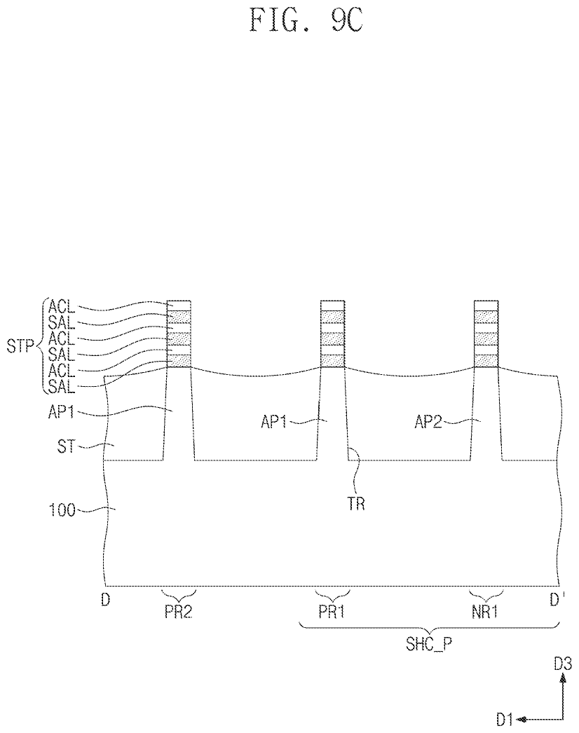

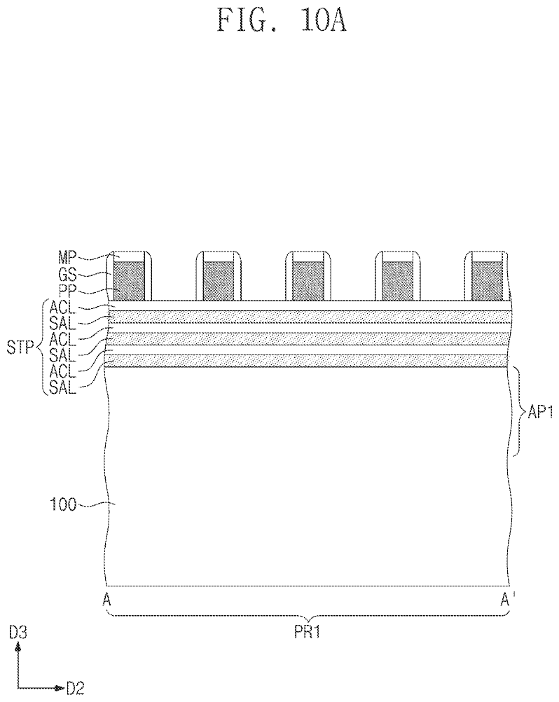

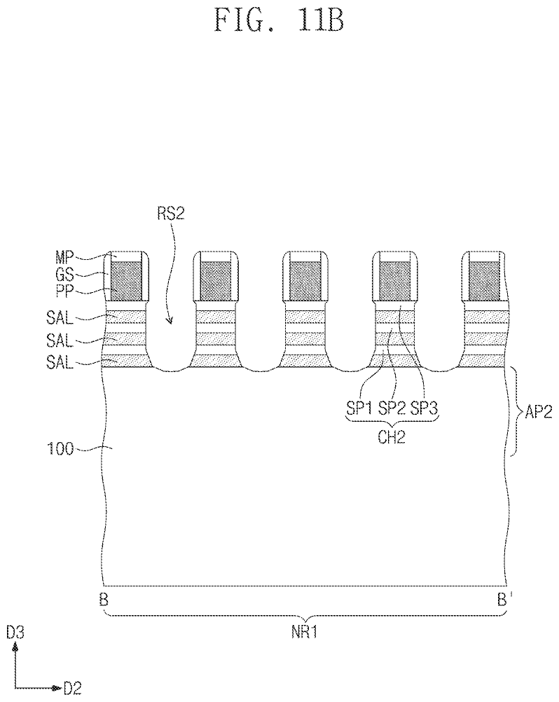

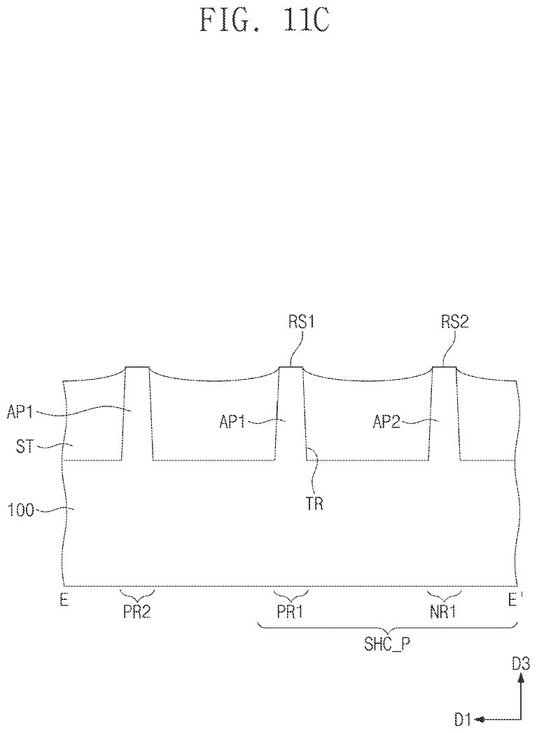

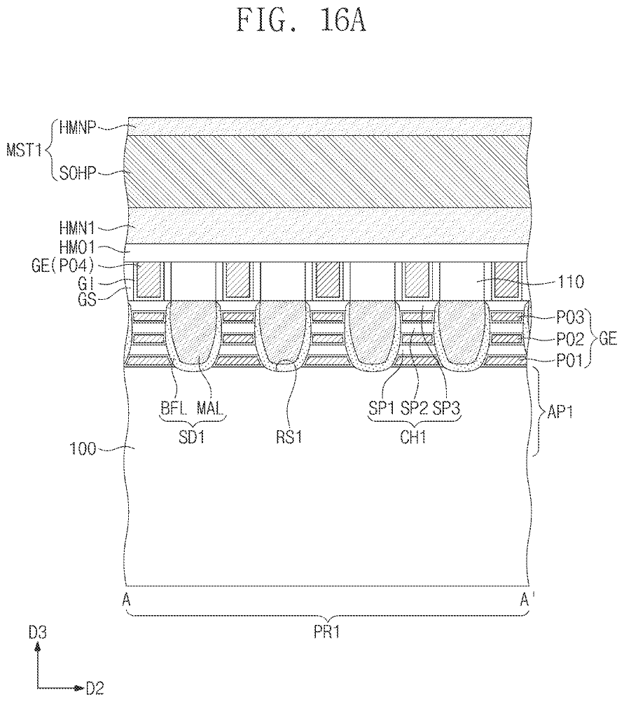

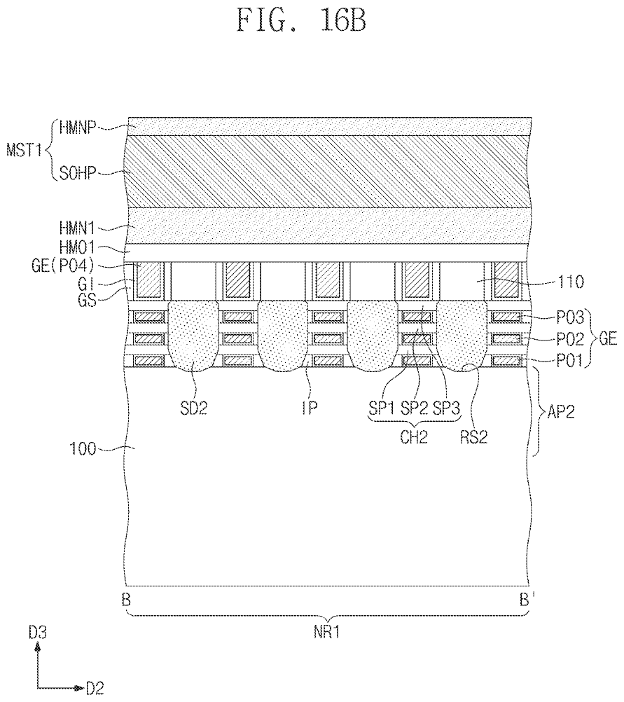

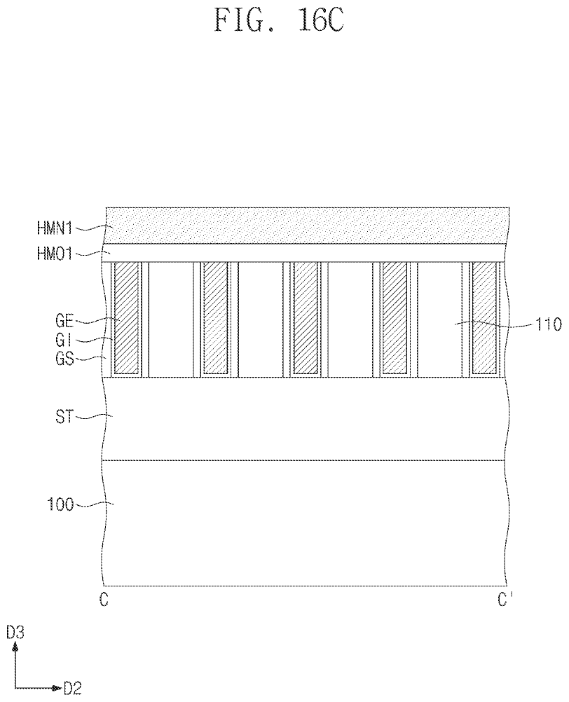

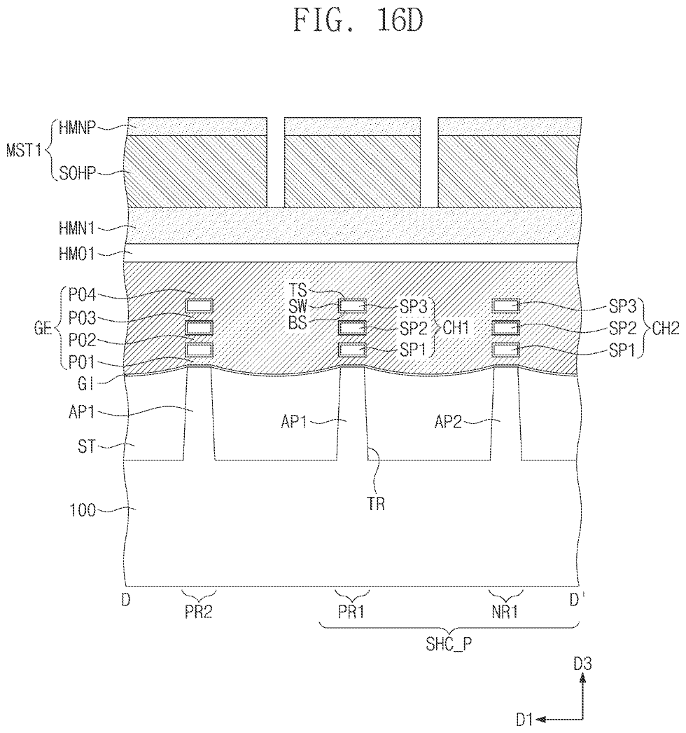

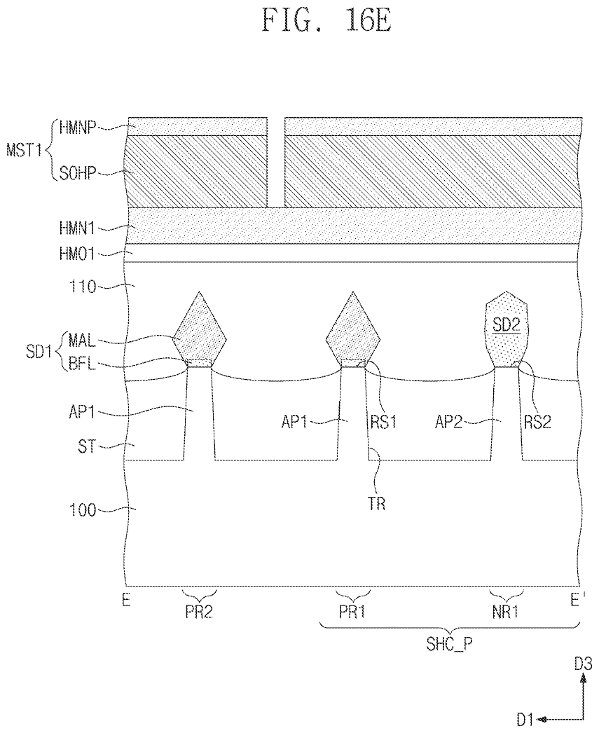

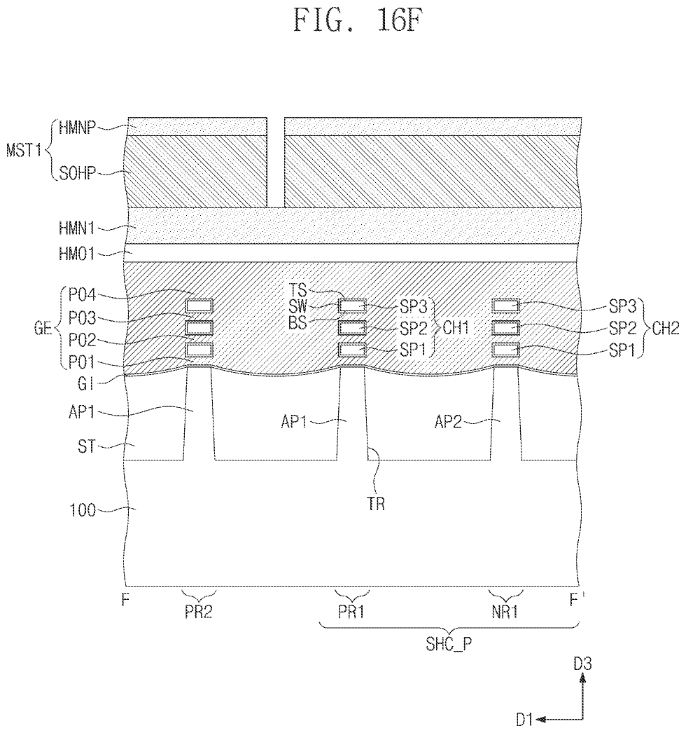

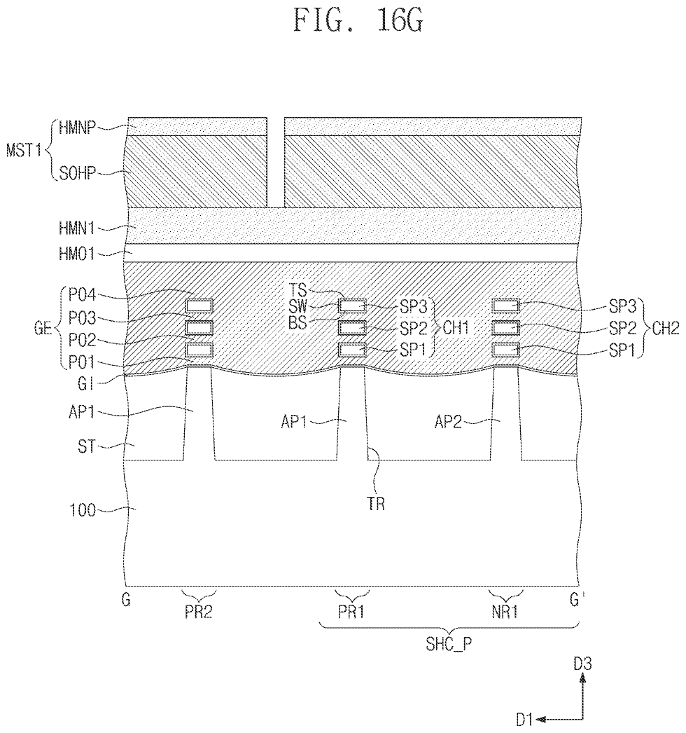

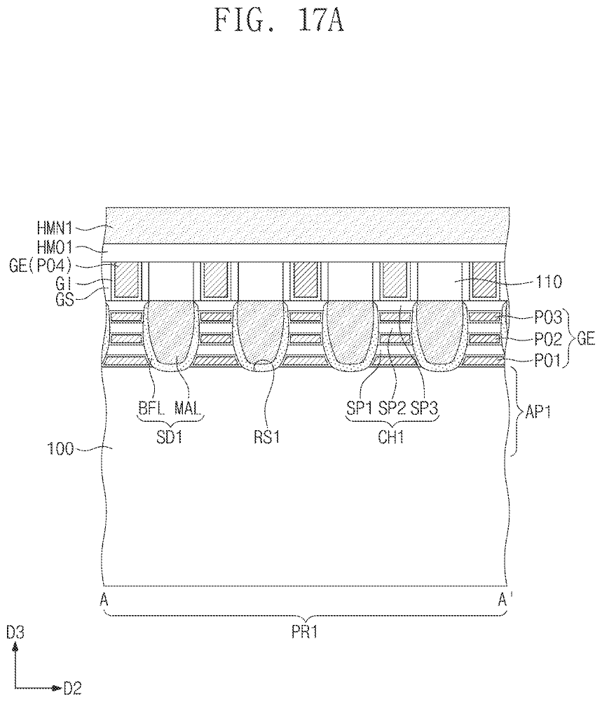

FIGS. 9A to 20G are sectional views illustrating a method of fabricating a semiconductor device, according to an implementation of the present disclosure. In detail, FIGS. 9A, 10A, 11A, 12A, 13A, 14A, 15A, 16A, 17A, 18A, 19A, and 20A are sectional views corresponding to the line A-A′ of FIG. 4. FIGS. 11B, 12B, 13B, 14B, 15B, 16B, 17B, 18B, 19B, and 20B are sectional views corresponding to the line B-B′ of FIG. 4. FIGS. 9B, 10B, 13C, 14C, 15C, 16C, 17C, 18C, 19C, and 20C are sectional views corresponding to the line C-C′ of FIG. 4. FIGS. 9C, 10C, 14D, 15D, 16D, 17D, 18D, 19D, and 20D are sectional views corresponding to the line D-D′ of FIG. 4. FIGS. 11C, 12C, 13D, 16E, 17E, 18E, 19E, and 20E are sectional views corresponding to the line E-E′ of FIG. 4. FIGS. 16F, 17F, 18F, 19F, and 20F are sectional views corresponding to the line F-F′ of FIG. 4. FIGS. 16G, 17G, 18G, 19G, and 20G are sectional views corresponding to the line G-G′ of FIG. 4.

Referring to FIGS. 9A to 9C, the substrate 100 including the first and second PMOSFET regions PR1 and PR2 and the first and second NMOSFET regions NR1 and NR2 may be provided. First semiconductor layers ACL and the second semiconductor layers SAL may be formed on the substrate 100 to be alternately stacked on top of each other. Each of the first and second semiconductor layers ACL and SAL may be formed of or include at least one of silicon (Si), germanium (Ge), or silicon-germanium (SiGe), but the first and second semiconductor layers ACL and SAL may be formed of different materials from each other.

The second semiconductor layer SAL may be formed of or include a material having an etch selectivity with respect to the first semiconductor layer ACL. For example, the first semiconductor layers ACL may be formed of or include silicon (Si), and the second semiconductor layers SAL may be formed of or include silicon-germanium (SiGe). A germanium concentration of each of the second semiconductor layers SAL may range from 10 at % to 30 at %.

Mask patterns may be respectively formed on the first and second PMOSFET regions PR1 and PR2 and the first and second NMOSFET regions NR1 and NR2 of the substrate 100. The mask pattern may be a line- or bar-shaped pattern that is extended in the second direction D2.

A patterning process using the mask patterns as an etch mask may be performed to form the trench TR defining the first and second active patterns AP1 and AP2. The first active pattern AP1 may be formed on each of the first and second PMOSFET regions PR1 and PR2. The second active pattern AP2 may be formed on each of the first and second NMOSFET regions NR1 and NR2. When viewed in a plan view, the first and second active patterns AP1 and AP2 may be line-shaped patterns, which are extended in the second direction D2 to be parallel to each other.

A stacking pattern STP may be formed on each of the first and second active patterns AP1 and AP2. The stacking pattern STP may include the first semiconductor layers ACL and the second semiconductor layers SAL, which are alternately stacked. During the patterning process, the stacking pattern STP may be formed together with the first and second active patterns AP1 and AP2. The stacking pattern STP may not be formed on the substrate 100 between the first and second PMOSFET regions PR1 and PR2 and between the first and second NMOSFET regions NR1 and NR2.

The device isolation layer ST may be formed to fill the trench TR. In detail, an insulating layer may be formed on the substrate 100 to cover the first and second active patterns AP1 and AP2 and the stacking patterns STP. The device isolation layer ST may be formed by recessing the insulating layer until the stacking patterns STP are exposed.

The device isolation layer ST may be formed of or include an insulating material (e.g., silicon oxide). The stacking patterns STP may be placed at a level higher than the device isolation layer ST and may be exposed to the outside of the device isolation layer ST. In other words, the stacking patterns STP may protrude vertically above the device isolation layer ST.

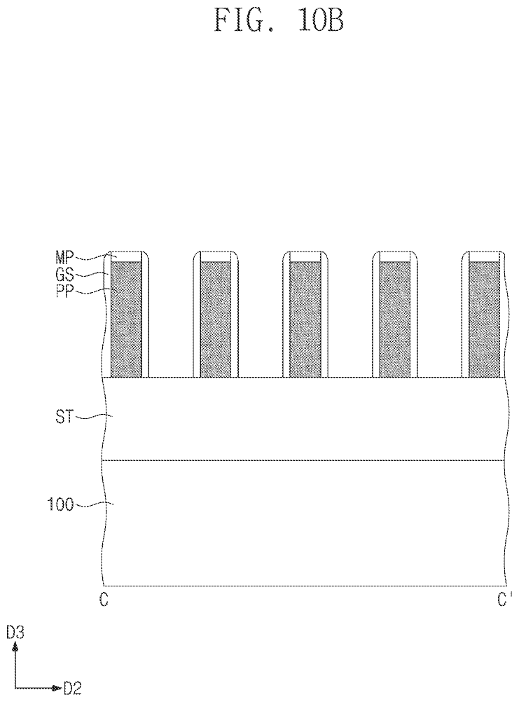

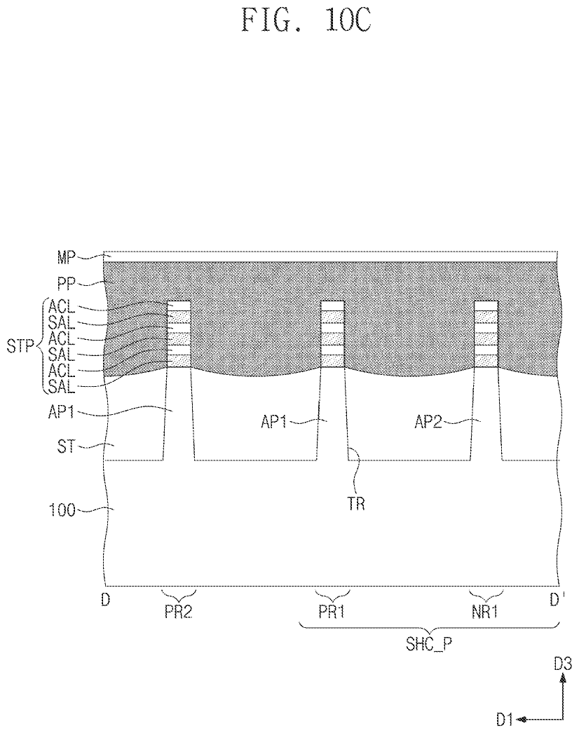

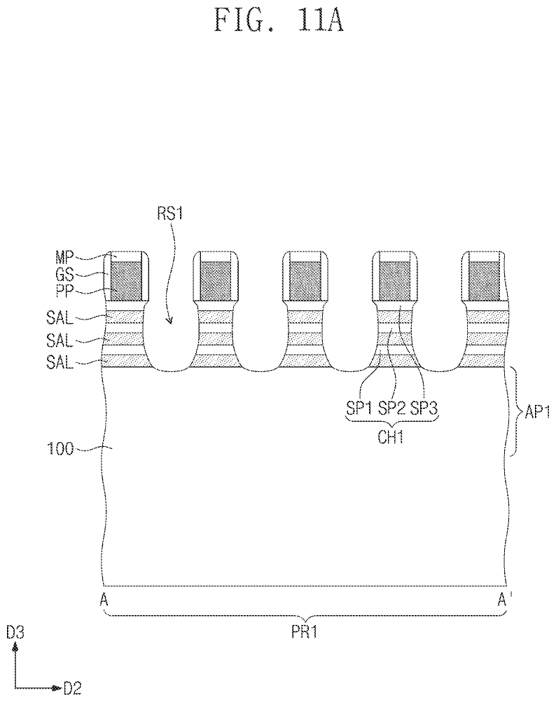

Referring to FIGS. 10A to 10C, sacrificial patterns PP may be formed on the substrate 100 to cross the stacking patterns STP. Each of the sacrificial patterns PP may be a line- or bar-shaped pattern that is extended in the first direction D1. The sacrificial patterns PP may be arranged at a first pitch in the second direction D2.

In detail, on each of the first and second PMOSFET regions PR1 and PR2 and the first and second NMOSFET regions NR1 and NR2, the sacrificial patterns PP on the stacking patterns STP may be formed to be spaced apart from each other in the second direction D2. The sacrificial patterns PP may be formed on portions of the device isolation layer ST, which are placed between the first and second PMOSFET regions PR1 and PR2 and between the first and second NMOSFET regions NR1 and NR2, to be spaced apart from each other in the second direction D2.

The formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may be formed of or include polysilicon.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. The gate spacer layer may be formed of or include at least one of SiCN, SiCON, or SiN. In an implementation, the gate spacer layer may be a multi-layered structure including at least two of SiCN, SiCON, or SiN.

Referring to FIGS. 11A to 11C, the first recesses RS1 may be formed in the stacking pattern STP on the first active pattern AP1. The second recesses RS2 may be formed in the stacking pattern STP on the second active pattern AP2. During the formation of the first and second recesses RS1 and RS2, the device isolation layer ST may also be recessed at both sides of each of the first and second active patterns AP1 and AP2 (e.g., see FIG. 9C).

In detail, the first recesses RS1 may be formed by etching the stacking pattern STP on the first active pattern AP1 using the hard mask patterns MP and the gate spacers GS as an etch mask. The first recess RS1 may be formed between a pair of the sacrificial patterns PP. The second recesses RS2 in the stacking pattern STP on the second active pattern AP2 may be formed by the same method as that for the first recesses RS1.

The first to third semiconductor patterns SP1, SP2, and SP3, which are sequentially stacked between adjacent ones of the first recesses RS1, may be formed from the first semiconductor layers ACL, respectively. The first to third semiconductor patterns SP1, SP2, and SP3, which are sequentially stacked between adjacent ones of the second recesses RS2, may be formed from the first semiconductor layers ACL, respectively. The first to third semiconductor patterns SP1, SP2, and SP3 between adjacent ones of the first recesses RS1 may constitute the first channel pattern CH1. The first to third semiconductor patterns SP1, SP2, and SP3 between the adjacent ones of the second recesses RS2 may constitute the second channel pattern CH2.

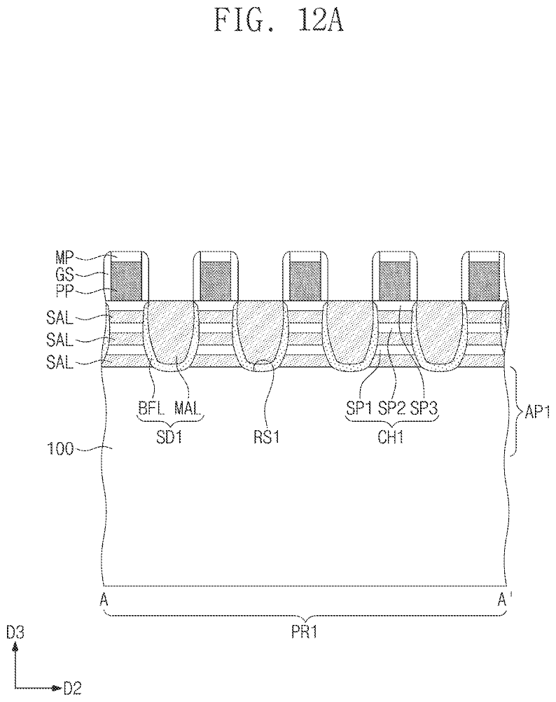

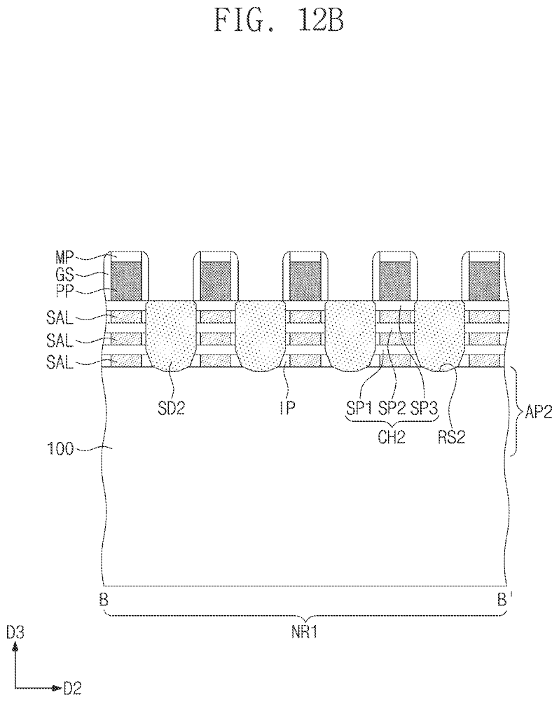

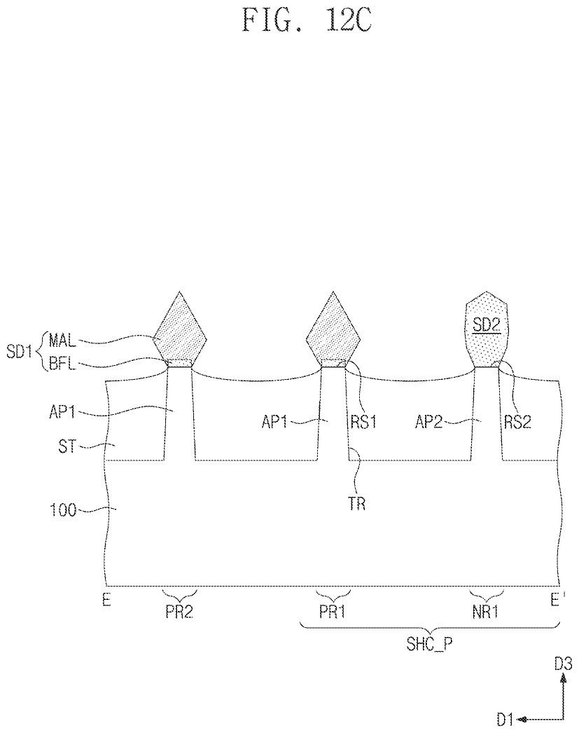

Referring to FIGS. 12A to 12C, the first source/drain patterns SD1 may be formed in the first recesses RS1, respectively. In detail, the buffer layer BFL may be formed by a first SEG process using an inner surface of the first recess RS1 as a seed layer. The buffer layer BFL may be grown using the first to third semiconductor patterns SP1, SP2, and SP3 and the substrate 100, which are exposed through the first recess RS1, as a seed layer. As an example, the first SEG process may include a chemical vapor deposition (CVD) process or a molecular beam epitaxy (MBE) process.

The buffer layer BFL may contain a semiconductor material (e.g., SiGe) whose lattice constant is larger than that of a semiconductor material of the substrate 100. The buffer layer BFL may contain a relatively low concentration of germanium (Ge). In another implementation, the buffer layer BFL may contain only silicon (Si), without germanium (Ge). The germanium concentration of the buffer layer BFL may range from 0 at % to 10 at %.

A second SEG process may be performed on the buffer layer BFL to form the main layer MAL. The main layer MAL may be formed to fill the first recess RS1 completely or nearly completely. The main layer MAL may contain a relatively high concentration of germanium. In an implementation, the germanium concentration of the main layer MAL may range from 30 at % to 70 at %.

In an implementation, a third SEG process may be performed on the main layer MAL to form a capping layer. The capping layer may be formed of or include silicon (Si). A silicon concentration of the capping layer may range from 98 at % to 100 at %.

During the formation of the buffer and main layers BFL and MAL, the first source/drain pattern SD1 may be doped in-situ with p-type impurities (e.g., boron, gallium, or indium). Alternatively, impurities may be injected into the first source/drain pattern SD1, after the formation of the first source/drain pattern SD1.

The second source/drain patterns SD2 may be formed in the second recesses RS2, respectively. In detail, the second source/drain pattern SD2 may be formed by a SEG process, in which an inner surface of the second recess RS2 is used as a seed layer. In an implementation, the second source/drain pattern SD2 may be formed of or include the same semiconductor material (e.g., Si) as the substrate 100.

During the formation of the second source/drain pattern SD2, the second source/drain pattern SD2 may be doped in-situ with n-type impurities (e.g., phosphorus, arsenic, or antimony). Alternatively, impurities may be injected into the second source/drain pattern SD2, after the formation of the second source/drain pattern SD2.

In an implementation, before the formation of the second source/drain pattern SD2, the inner spacer IP may be formed by replacing a portion of the second semiconductor layer SAL, which is exposed by the second recess RS2, with an insulating material. As a result, the inner spacers IP may be respectively formed between the second source/drain pattern SD2 and the second semiconductor layers SAL.

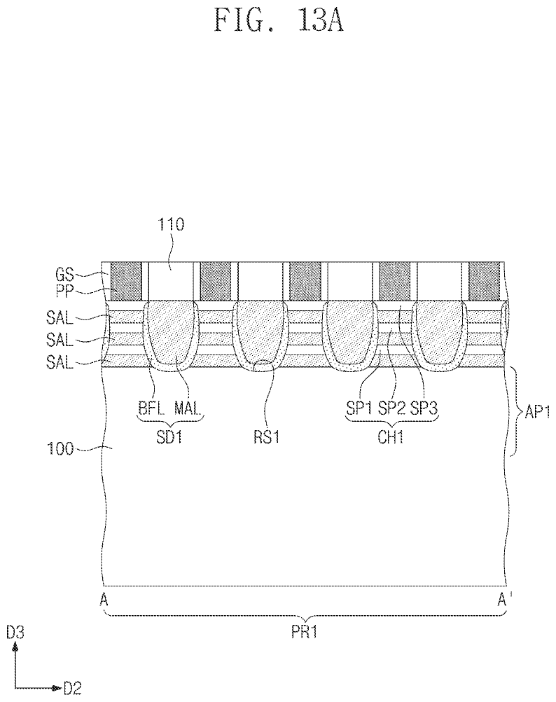

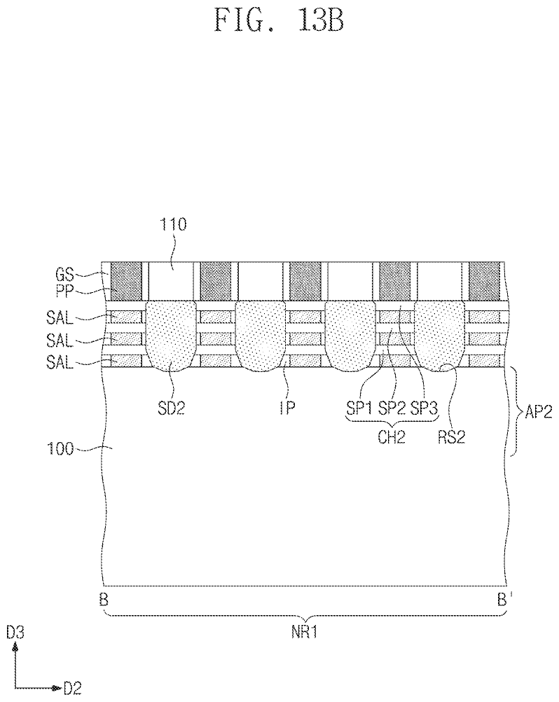

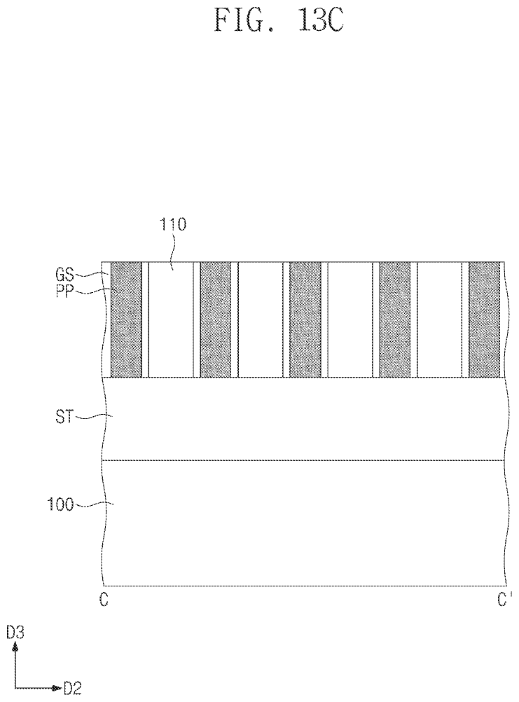

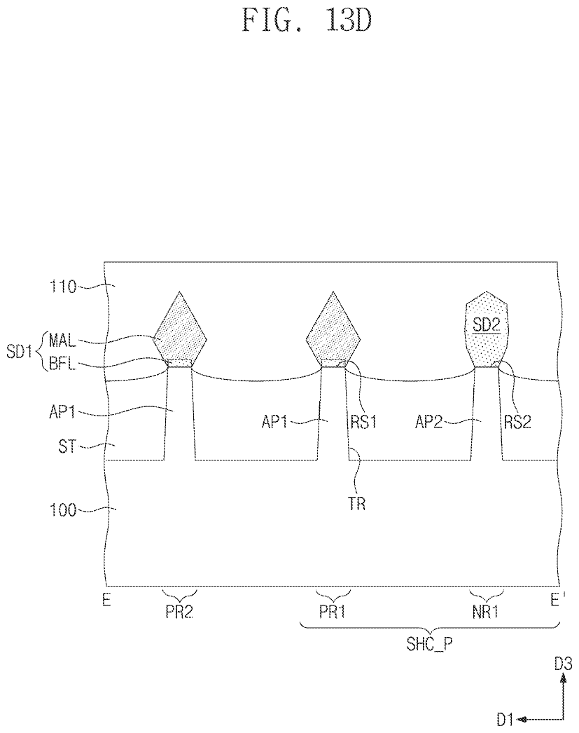

Referring to FIGS. 13A to 13D, the first interlayer insulating layer 110 may be formed to cover the first and second source/drain patterns SD1 and SD2, the hard mask patterns MP, the gate spacers GS, and the device isolation layer ST. In an implementation, the first interlayer insulating layer 110 may include a silicon oxide layer.

The first interlayer insulating layer 110 may be planarized to expose top surfaces of the sacrificial patterns PP. The planarization of the first interlayer insulating layer 110 may be performed using an etch-back or chemical-mechanical polishing (CMP) process. During the planarization process, all of the hard mask patterns MP may be removed. As a result, the top surface of the first interlayer insulating layer 110 may be coplanar with the top surfaces of the sacrificial patterns PP and the top surfaces of the gate spacers GS.

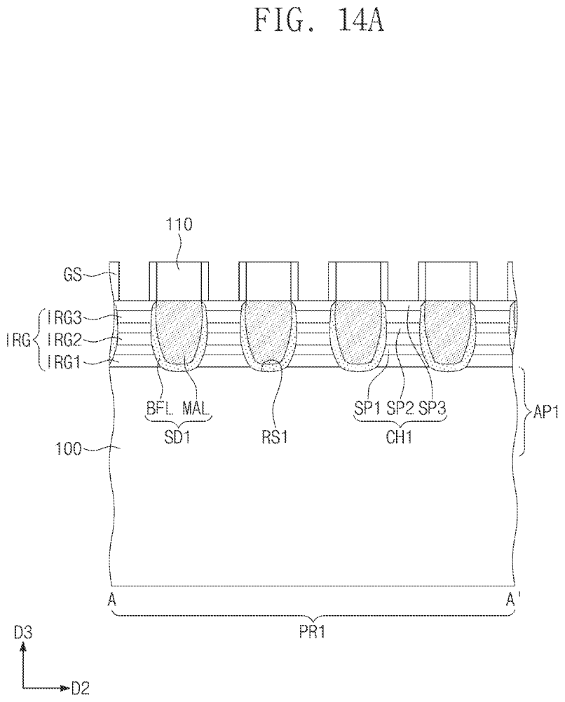

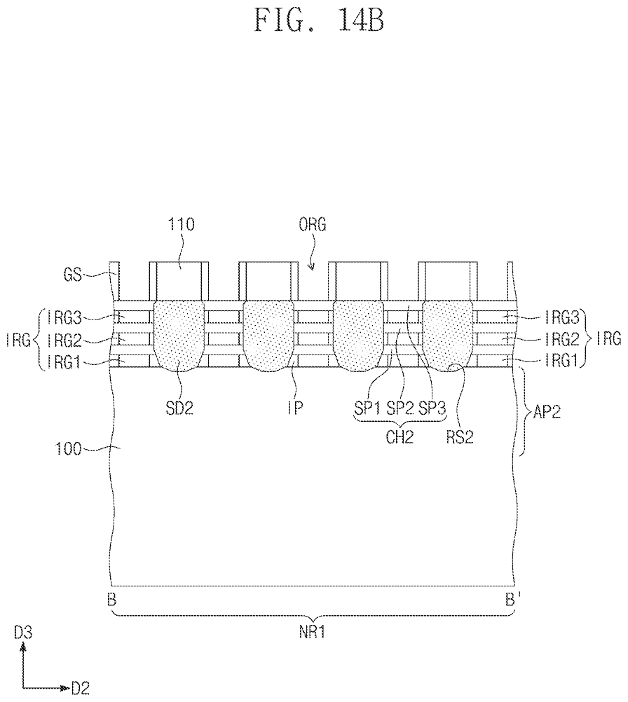

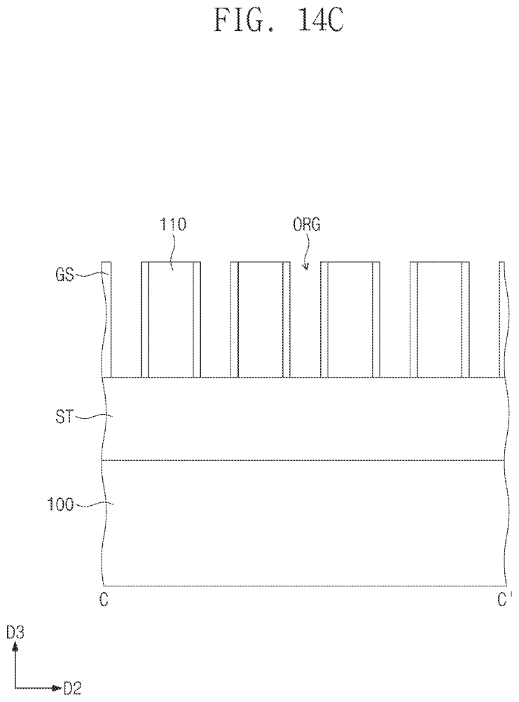

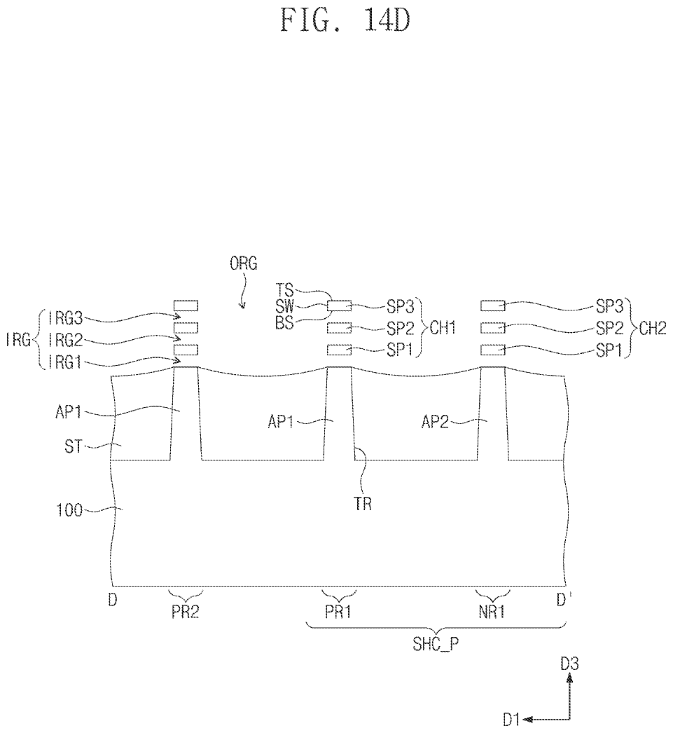

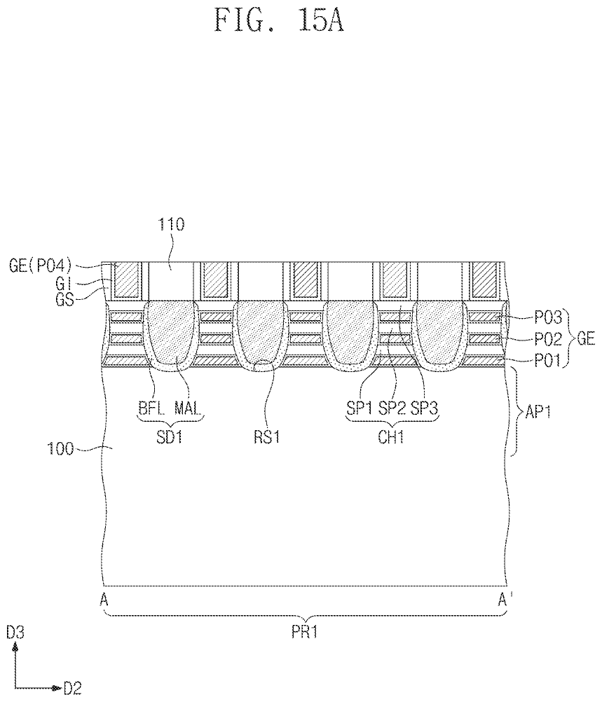

Referring to FIGS. 14A to 14D, a photolithography process may be performed to selectively open a region of the sacrificial pattern PP. For example, a region of the sacrificial pattern PP on the borders of the edge cell SHC_P may be selectively opened. The opened region of the sacrificial pattern PP may be selectively etched and removed.

The exposed sacrificial patterns PP may be selectively removed. As a result of the removal of the sacrificial patterns PP, an outer region ORG may be formed to expose the first and second channel patterns CH1 and CH2 (e.g., see FIG. 14D). The removal of the sacrificial patterns PP may include a wet etching process which is performed using an etching solution capable of selectively etching polysilicon.

Referring to FIG. 14C, a wet etching process may be performed to selectively remove the sacrificial patterns PP through the opened region. In the wet etching process, the gate spacer GS and the device isolation layer ST may have a lower etch rate than the sacrificial patterns PP, and in this case, the gate spacer GS and the device isolation layer ST may not be etched by the wet etching process. As a result, the sacrificial patterns PP may be selectively removed to expose the top surface of the device isolation layer ST.

The second semiconductor layers SAL, which are exposed through the outer region ORG, may be selectively removed to form inner regions IRG (e.g., see FIG. 14D). In detail, an etching process of selectively etching the second semiconductor layers SAL may be performed to leave the first to third semiconductor patterns SP1, SP2, and SP3 and to remove only the second semiconductor layers SAL. An etch recipe for the etching process may be chosen to etch a layer (e.g., a silicon germanium layer), which is formed to have a relatively high germanium concentration, at a high etch rate. For example, the etching process may be chosen to have a high etch rate to a silicon germanium layer whose germanium concentration is higher than 10 at %.

During the etching process, the second semiconductor layers SAL may be completely removed from the first and second PMOSFET regions PR1 and PR2 and the first and second NMOSFET regions NR1 and NR2. The etching process may be a wet etching process. An etchant material, which is used in the etching process, may be chosen to quickly remove the second semiconductor layer SAL having a relatively high germanium concentration. Meanwhile, the first source/drain patterns SD1 on the first and second PMOSFET regions PR1 and PR2 may be protected from the etching process by the buffer layer BFL having a relatively low germanium concentration.

Referring back to FIG. 14D, as a result of the selective removal of the second semiconductor layers SAL, the stacked first to third semiconductor patterns SP1, SP2, and SP3 may be left on each of the first and second active patterns AP1 and AP2. Empty regions, which are formed by removing the second semiconductor layers SAL, may be used as first to third inner regions IRG1, IRG2, and IRG3, respectively.

In detail, a first inner region IRG1 may be formed between the active pattern AP1 or AP2 and the first semiconductor pattern SP1, a second inner region IRG2 may be formed between the first semiconductor pattern SP1 and the second semiconductor pattern SP2, and a third inner region IRG3 may be formed between the second semiconductor pattern SP2 and the third semiconductor pattern SP3.

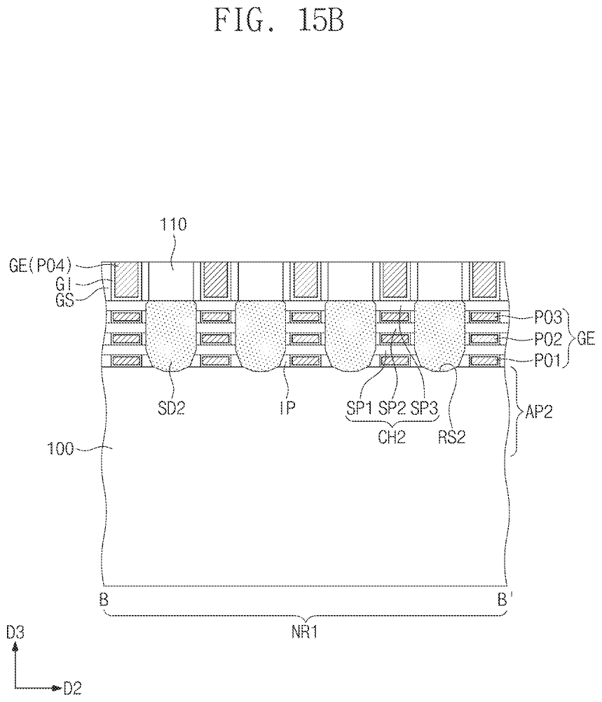

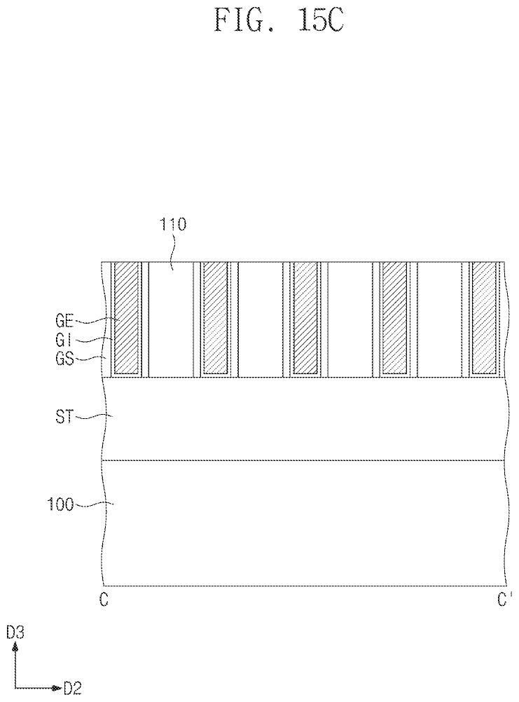

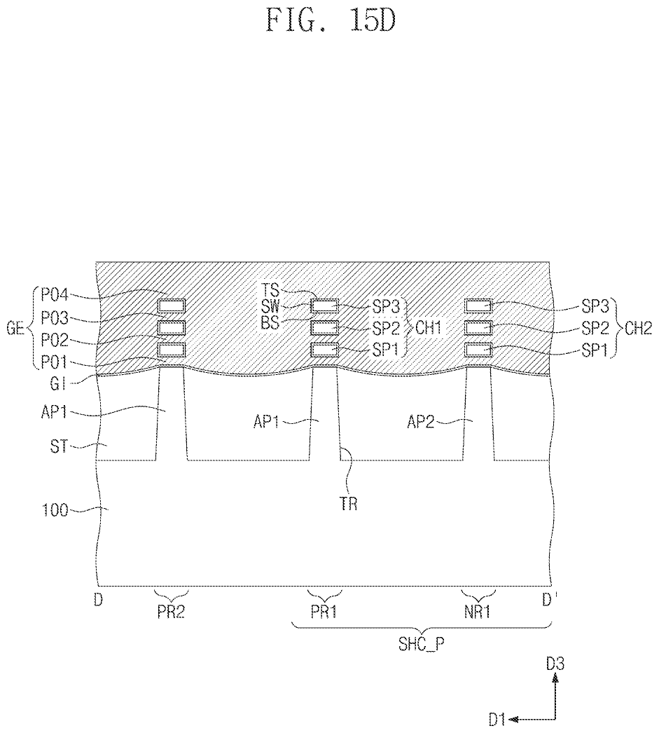

Referring to FIGS. 15A to 15D, the gate insulating layer GI may be conformally formed on the exposed first to third semiconductor patterns SP1, SP2, and SP3. The gate electrode GE may be formed on the gate insulating layer GI. The gate electrode GE may include first to third inner electrodes PO1, PO2, and PO3, which are respectively formed in the first to third inner regions IRG1, IRG2, and IRG3, and an outer electrode PO4, which is formed in the outer region ORG. Although not shown, the gate capping pattern may be formed on the gate electrode GE.

Referring to FIG. 15C, the gate insulating layer GI may be formed on the exposed top surface of the device isolation layer ST and the exposed side surface of the gate spacer GS. The gate electrode GE may be formed on the gate insulating layer GI. The gate electrode GE, which is formed on the device isolation layer ST, may serve as a dummy gate electrode. The top surface of the gate electrode GE may be coplanar with the top surface of the gate spacer GS, the top surface of the gate insulating layer GI, and the top surface of the first interlayer insulating layer 110.

Referring to FIG. 15D, the gate insulating layer GI may be conformally formed on the exposed first to third semiconductor patterns SP1, SP2, and SP3. In detail, the gate insulating layer GI may enclose the top surface TS, the bottom surface BS, and the opposite side surfaces SW of each of the first to third semiconductor patterns SP1, SP2, and SP3. The first inner electrode PO1 may be interposed between the first active pattern AP1 and the first semiconductor pattern SP1. The second inner electrode PO2 may be interposed between the first semiconductor pattern SP1 and the second semiconductor pattern SP2. The third inner electrode PO3 may be interposed between the second semiconductor pattern SP2 and the third semiconductor pattern SP3. The outer electrode PO4 may be provided on the third semiconductor pattern SP3.

Referring to FIGS. 16A to 16G, a first mask layer HMO1 may be formed on the gate electrode GE and the first interlayer insulating layer 110. A second mask layer HMN1 may be formed on the first mask layer HMO1. A first mask structure MST1 may be formed on the second mask layer HMN1.

The first mask structure MST1 may include a third mask layer SOHP on the second mask layer HMN1 and a fourth mask layer HMNP on the third mask layer SOHP.

The first mask layer HMO1 may be formed of or include silicon oxide. The first mask layer HMO1 may be a silicon oxide layer, which is deposited by an atomic layer deposition (ALD) process. For example, a thickness of the first mask layer HMO1 may range from 120 Å to 180 Å.

The second mask layer HMN1 may be formed of or include a material having an etch selectivity with respect to the first mask layer HMO1. The second mask layer HMN1 may be formed of or include silicon nitride. The second mask layer HMN1 may be a silicon nitride layer, which is deposited by a chemical vapor deposition (CVD) process. For example, the second mask layer HMN1 may be formed of or include plasma-enhanced silicon nitride (PE-SiN). A thickness of the second mask layer HMN1 may range from 1550 Å to 1650 Å.

The third mask layer SOHP may be formed of or include a material having an etch selectivity with respect to the second mask layer HMN1. The third mask layer SOHP may be formed of or include at least one of spin-on hardmask (SOH) materials. Referring to FIGS. 16C, 16D, 16F, and 16G, the third mask layer SOHP may include recessed regions, which are formed between the first and second PMOSFET regions PR1 and PR2 and between the first PMOSFET and NMOSFET regions PR1 and NR1 by a first photolithography process. Referring to FIG. 16E, the third mask layer SOHP may include a recessed region, which is formed between the first and second PMOSFET regions PR1 and PR2 by the first photolithography process. In other words, the third mask layer SOHP may be a pattern including the recessed regions, which are extended in the second direction D2 and are spaced apart from each other in the first direction D1.

The fourth mask layer HMNP may be formed of or include a material having an etch selectivity with respect to the third mask layer SOHP. The fourth mask layer HMNP may be formed of or include silicon oxynitride. For example, the fourth mask layer HMNP may be formed of or include silicon (Si) or silicon oxynitride (SiON). A thickness of the fourth mask layer HMNP may range from 200 Å to 300 Å.

The fourth mask layer HMNP may be a pattern which is formed based on a layout design rule. Referring back to FIGS. 16C, 16D, 16F, and 16G, the fourth mask layer HMNP may be a pattern which is formed to have an opened region between the first and second PMOSFET regions PR1 and PR2 and an opened region between the first PMOSFET and NMOSFET regions PR1 and NR1. Referring to FIG. 16E, the fourth mask layer HMNP may be a pattern that includes an opened region, which is located between the first and second PMOSFET regions PR1 and PR2.

In detail, the formation of the first mask structure MST1 may include forming a first preliminary mask layer on the second mask layer HMN1, forming the fourth mask layer HMNP on the first preliminary mask layer, and performing a first photolithography process on the first preliminary mask layer through the opened region of the fourth mask layer HMNP.

The first photolithography process may include performing a pre-cleaning process on the first preliminary mask layer and the fourth mask layer HMNP and performing an exposure and developing process on the first preliminary mask layer. For example, the exposure process may be an extreme ultraviolet (EUV) exposure process. As a result of the developing process, the first preliminary mask layer may be formed as the third mask layer SOHP.

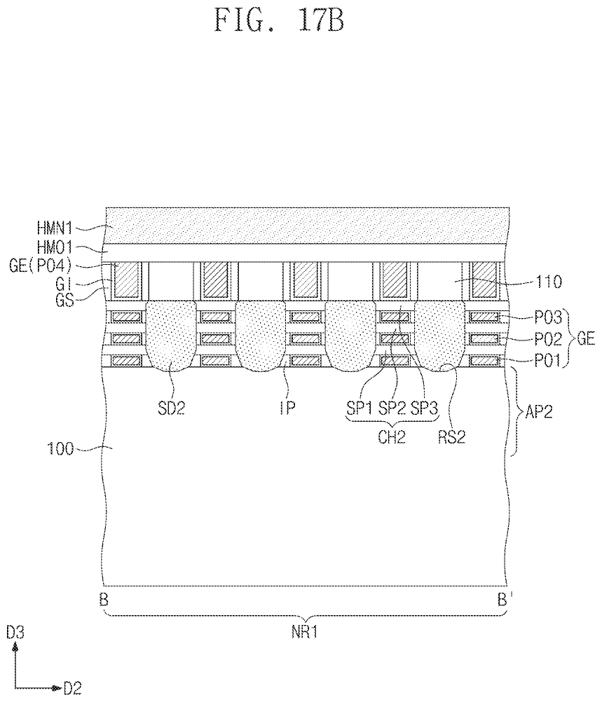

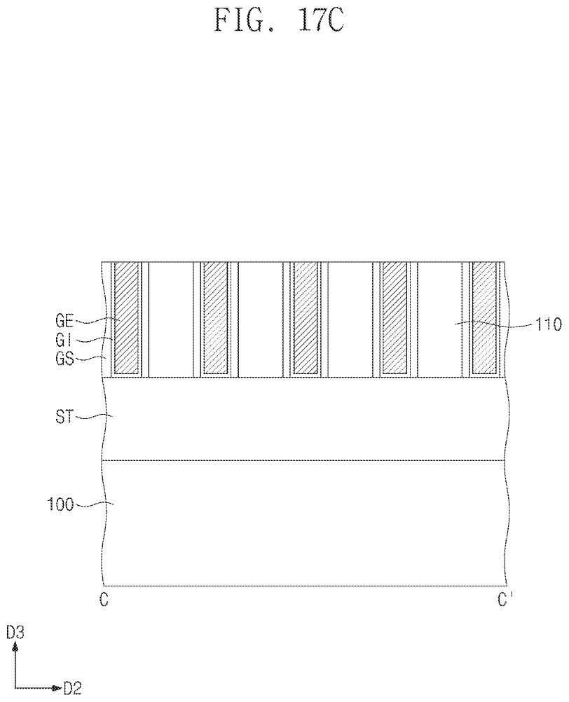

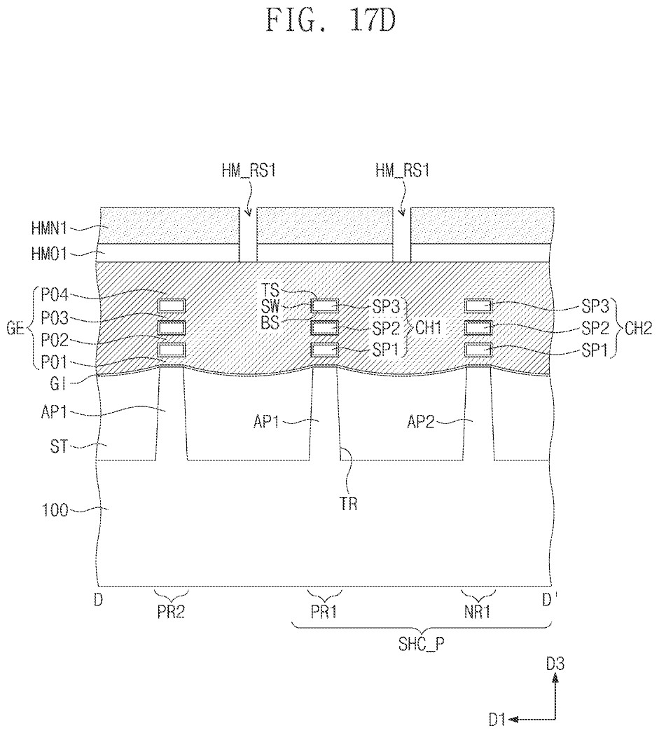

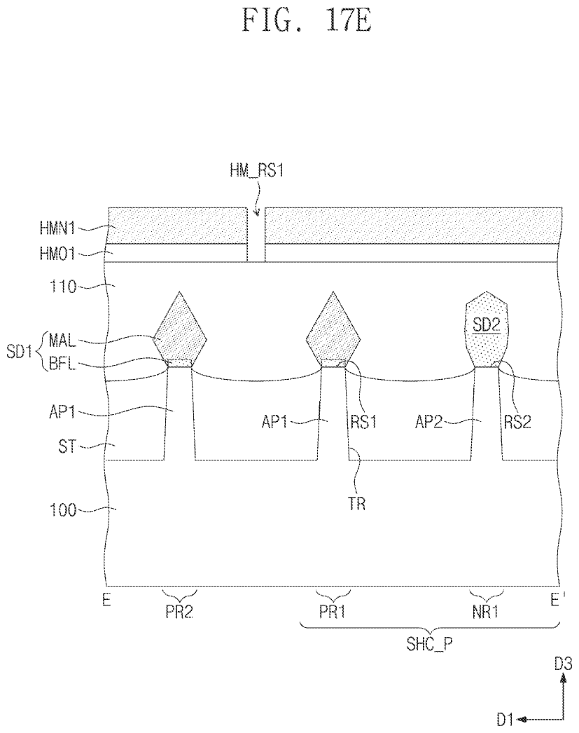

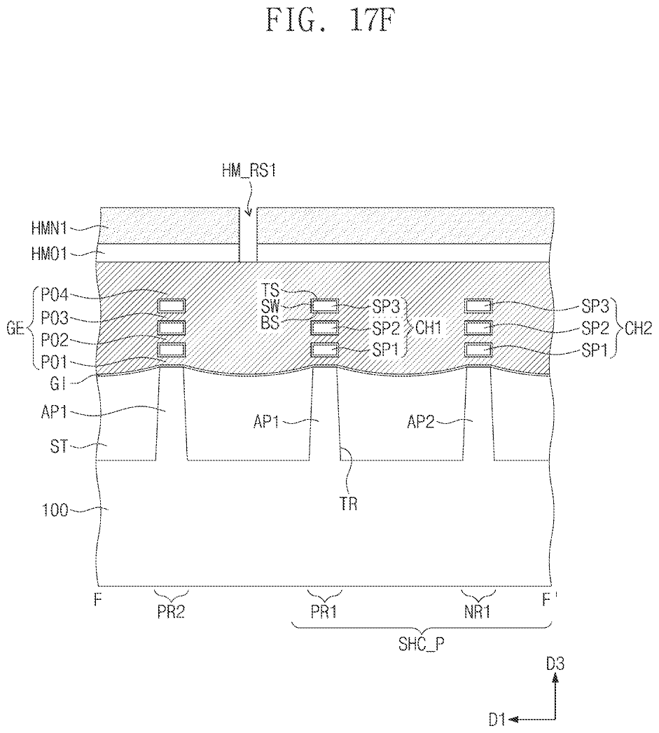

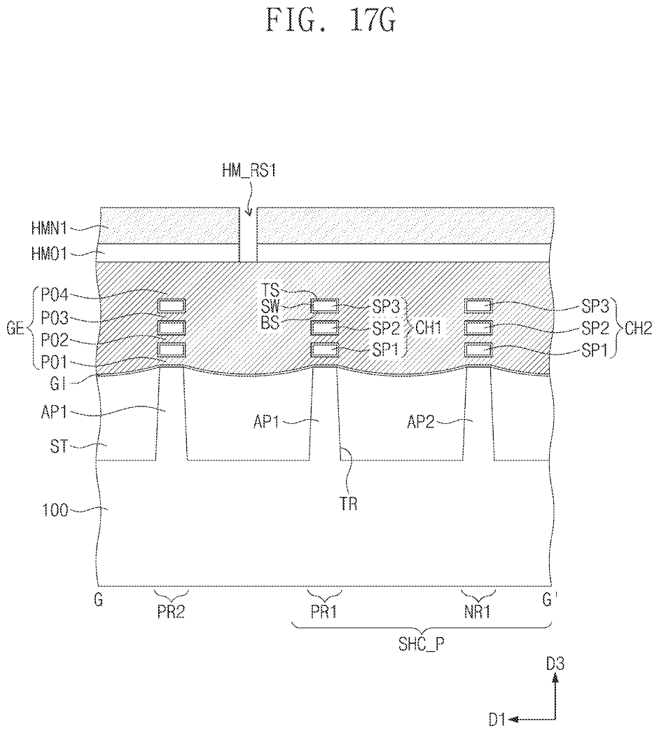

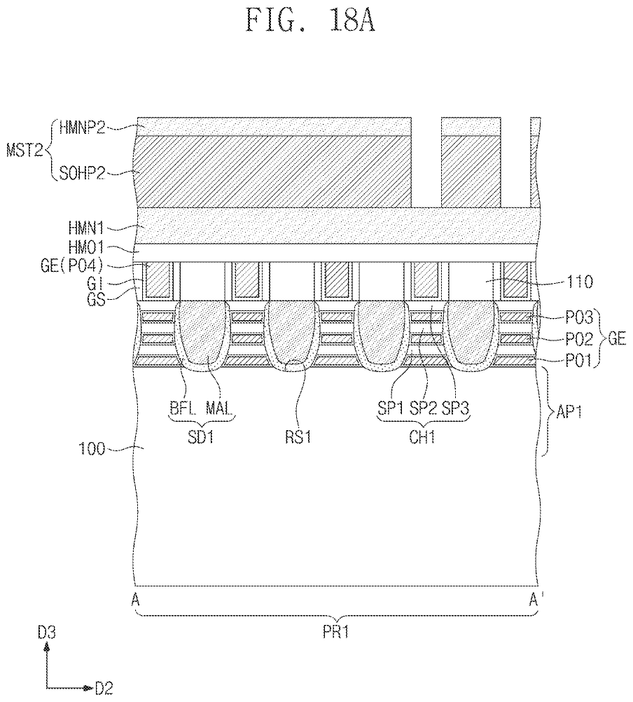

Referring to FIGS. 17A to 17G, a first etching process using the first mask structure MST1 of FIG. 16D as an etch mask may be performed on the first and second mask layers HMO1 and HMN1. The first etching process may be an anisotropic dry etching process. An etching gas or etchant material for the first etching process may be chosen to etch the first and second mask layers HMO1 and HMN1. For example, the etching gas or etchant material may be chosen to etch silicon oxide and silicon nitride.

As a result of the first etching process, the first and second mask layers HMO1 and HMN1 may be formed to include a first etch recess region HM_RS1. The first etch recess region HM_RS1 may correspond to the opened region of the first mask structure MST1 described with reference to FIG. 16D. Referring to FIGS. 17C, 17D, 17F, and 17G, the first etch recess region HM_RS1 may be located between the first and second PMOSFET regions PR1 and PR2 and between the first PMOSFET and NMOSFET regions PR1 and NR1. Referring to FIG. 17E, the first etch recess region HM_RS1 may be placed between the first and second PMOSFET regions PR1 and PR2.

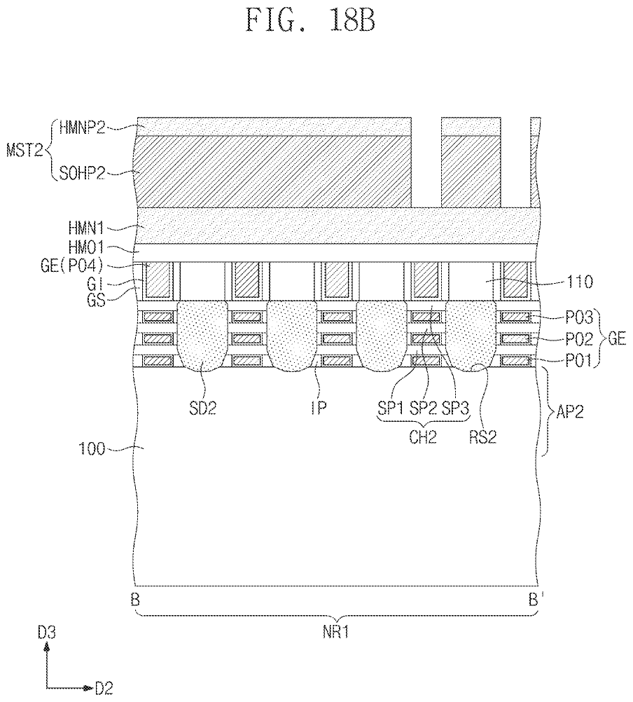

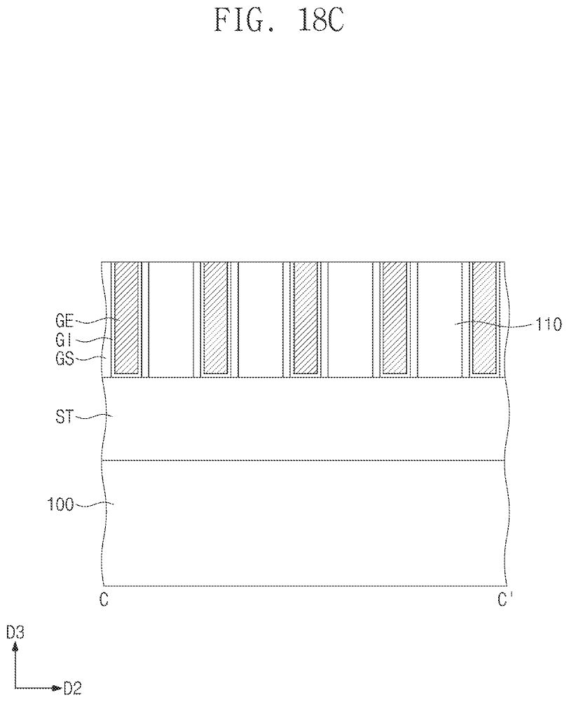

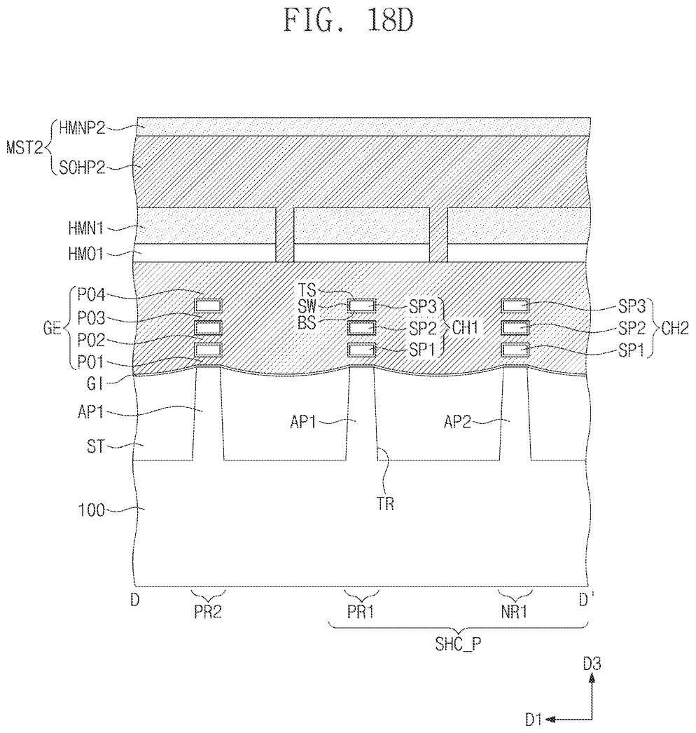

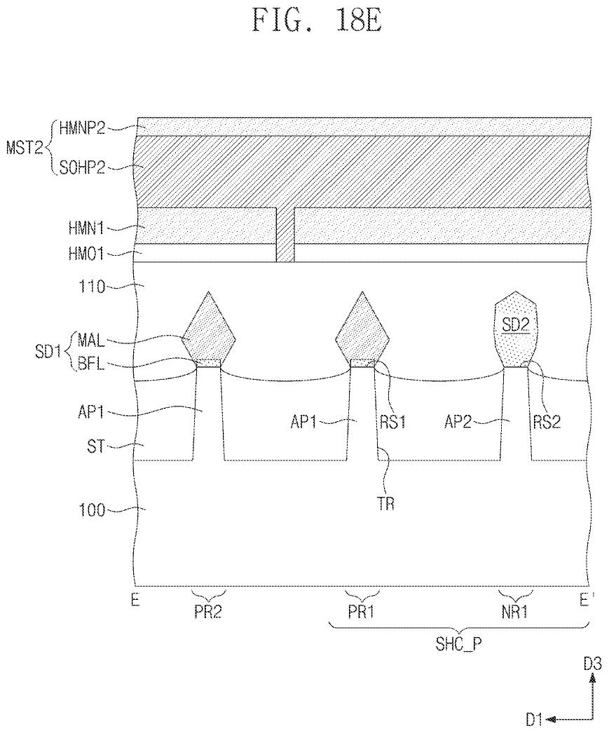

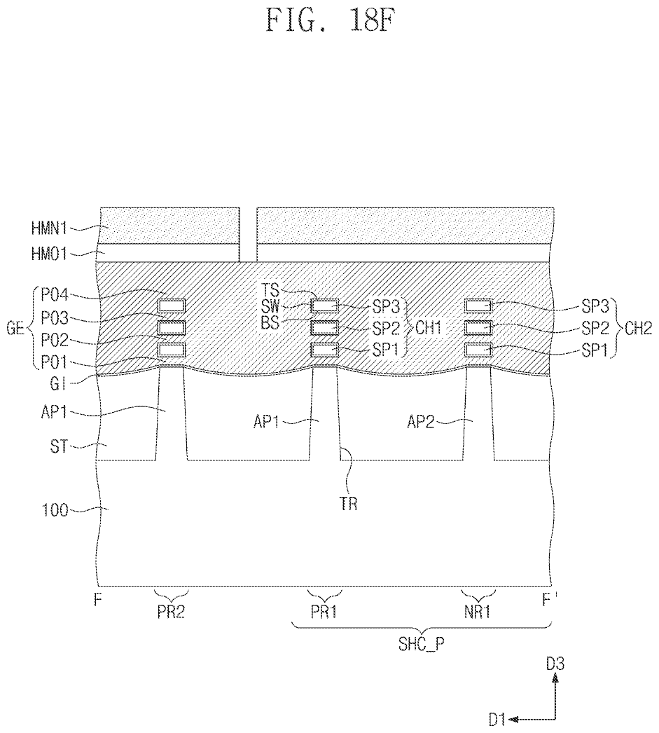

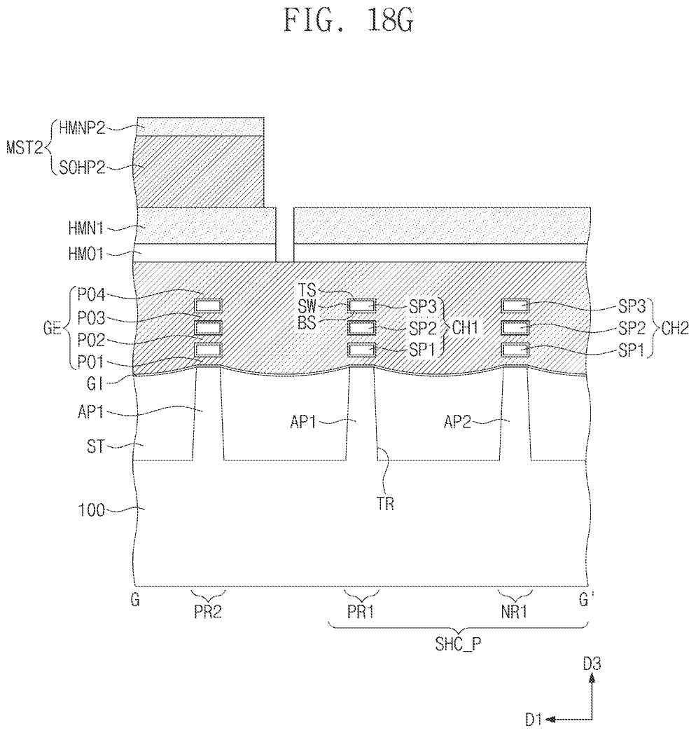

Referring to FIGS. 18A to 18G, a second mask structure MST2 may be formed on the substrate 100. The second mask structure MST2 may include a fifth mask layer SOHP2 on the second mask layer HMN1 and a sixth mask layer HMNP2 on the fifth mask layer SOHP2.

The fifth mask layer SOHP2 may be formed of or include a material having an etch selectivity with respect to the second mask layer HMN1. The fifth mask layer SOHP2 may be formed of or include at least one of spin-on hardmask (SOH) materials. Referring to FIGS. 18A, 18B, 18C, 18F, and 18G, the fifth mask layer SOHP2 may include a recessed region, which is formed on the gate electrode GE of the first PMOSFET region PR1 by a second photolithography process. In addition, the fifth mask layer SOHP2 may include a recessed region, which is formed on the gate electrode GE of the first NMOSFET region NR1 by the second photolithography process. In other words, the fifth mask layer SOHP2 may be a pattern including recessed regions, which are extended in the first direction D1 and are spaced apart from each other in the second direction D2.

The sixth mask layer HMNP2 may be formed of or include a material having an etch selectivity with respect to the fifth mask layer SOHP2. The sixth mask layer HMNP2 may be formed of or include silicon oxynitride. For example, the sixth mask layer HMNP2 may be formed of or include silicon (Si) or silicon oxynitride (SiON).

The sixth mask layer HMNP2 may be a pattern which is formed based on a layout design rule. Referring back to FIGS. 18A, 18B, 18C, 18F, and 18G, the sixth mask layer HMNP2 may be a pattern which is formed to have an opened region on the gate electrode GE of the first PMOSFET region PR1 and an opened region on the gate electrode GE of the first NMOSFET region NR1.

In detail, the formation of the second mask structure MST2 may include forming a second preliminary mask layer on the second mask layer HMN1, forming the sixth mask layer HMNP2 on the second preliminary mask layer, and performing the second photolithography process on the second preliminary mask layer through the opened region of the sixth mask layer HMNP2.

The formation of the second photolithography process may include performing a pre-cleaning process on the second preliminary mask layer and the sixth mask layer HMNP2 and performing an exposure and developing process on the second preliminary mask layer. For example, the exposure process may be an ArF exposure process. As a result of the developing process, the second preliminary mask layer may be formed as the fifth mask layer SOHP2.

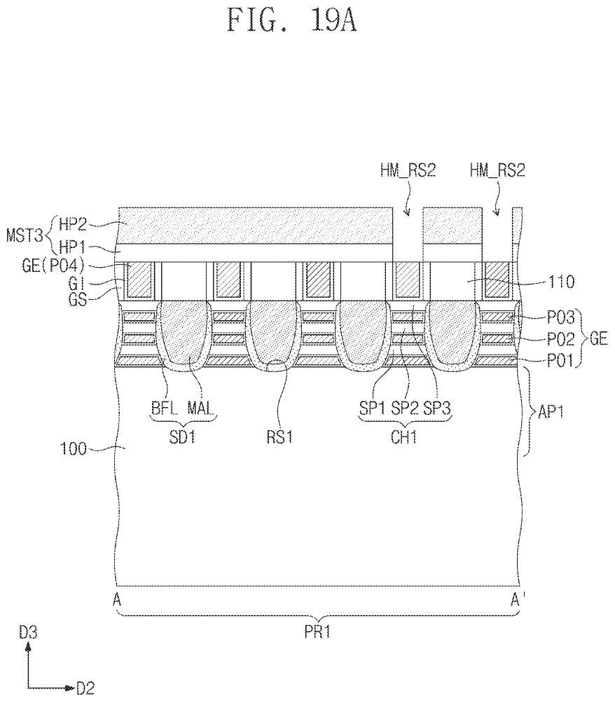

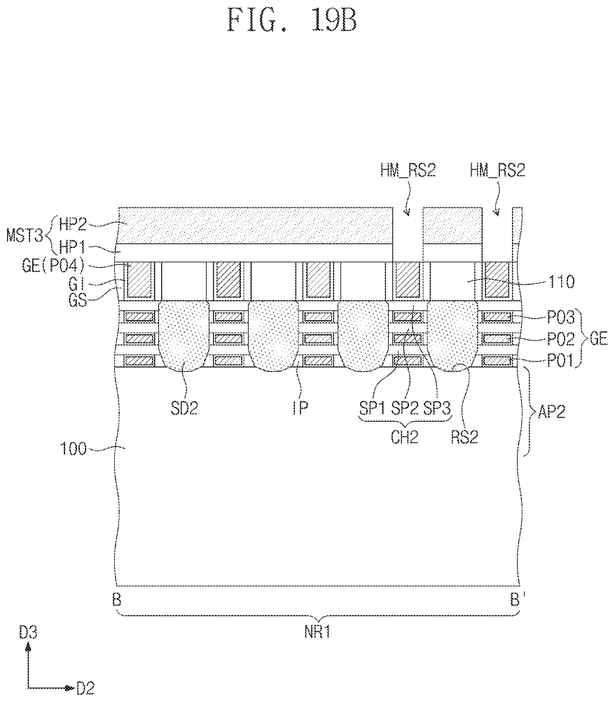

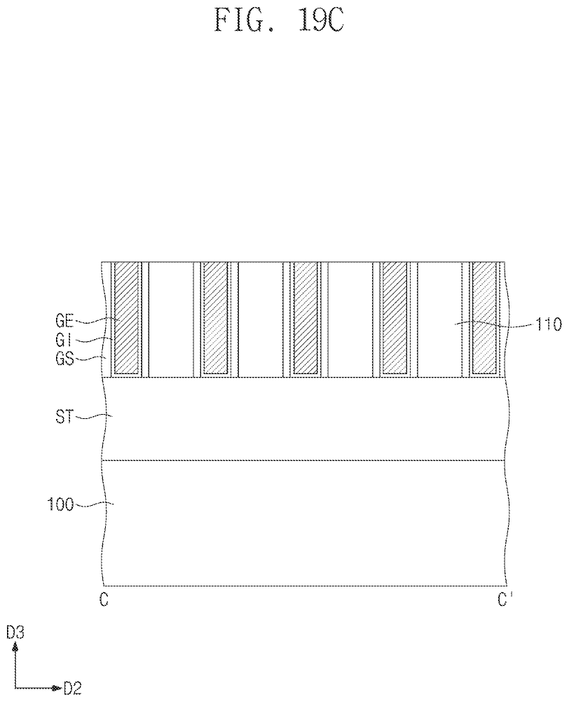

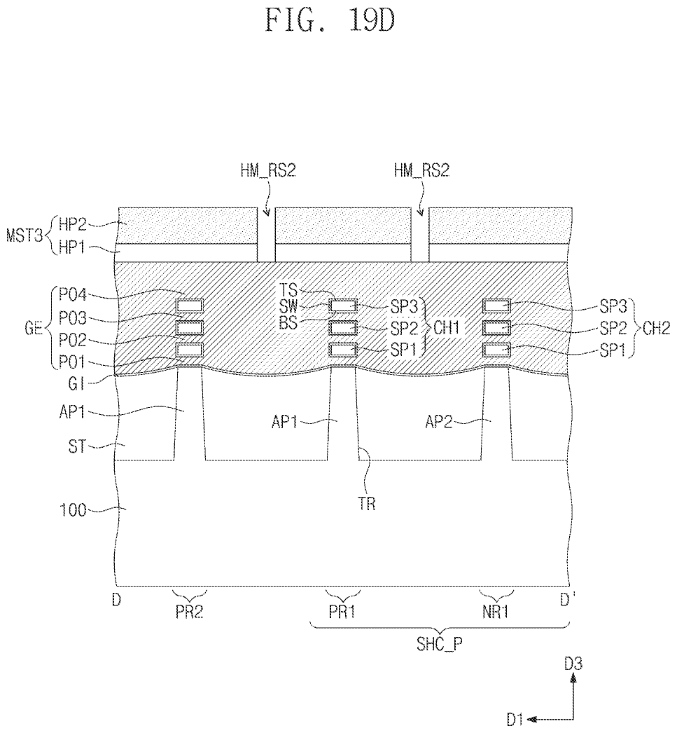

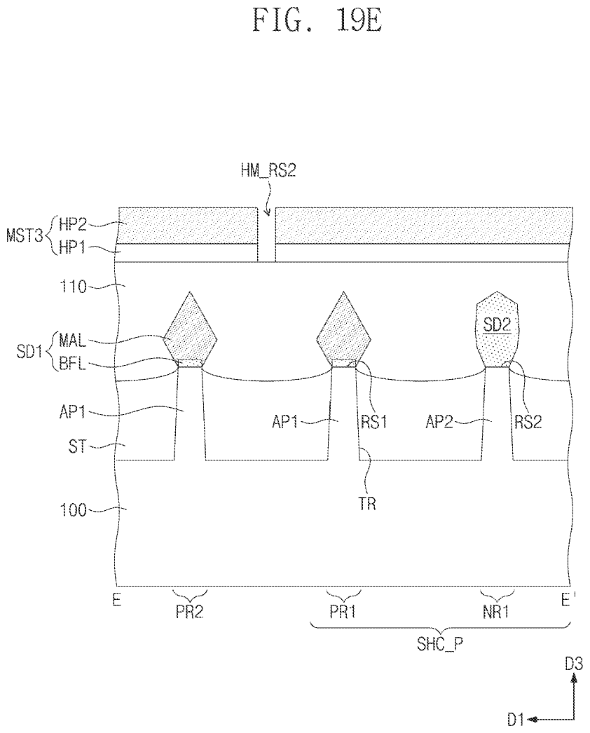

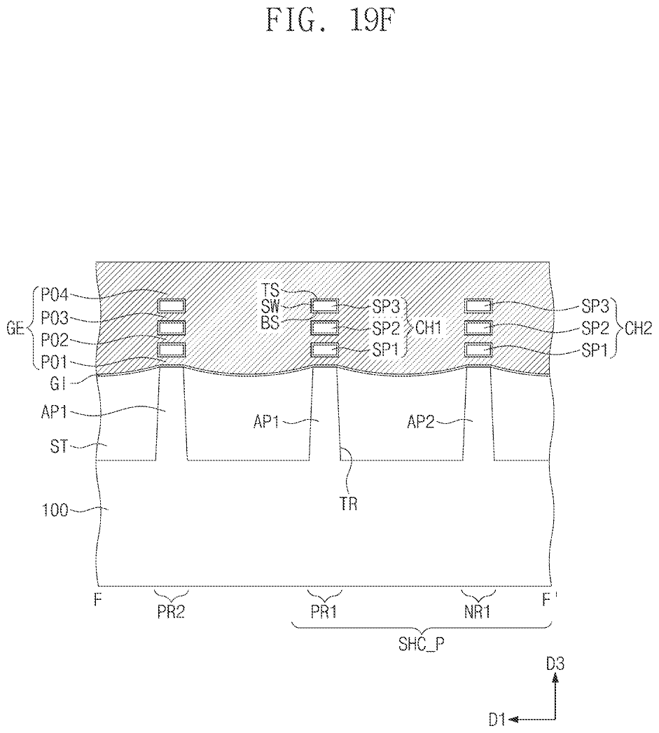

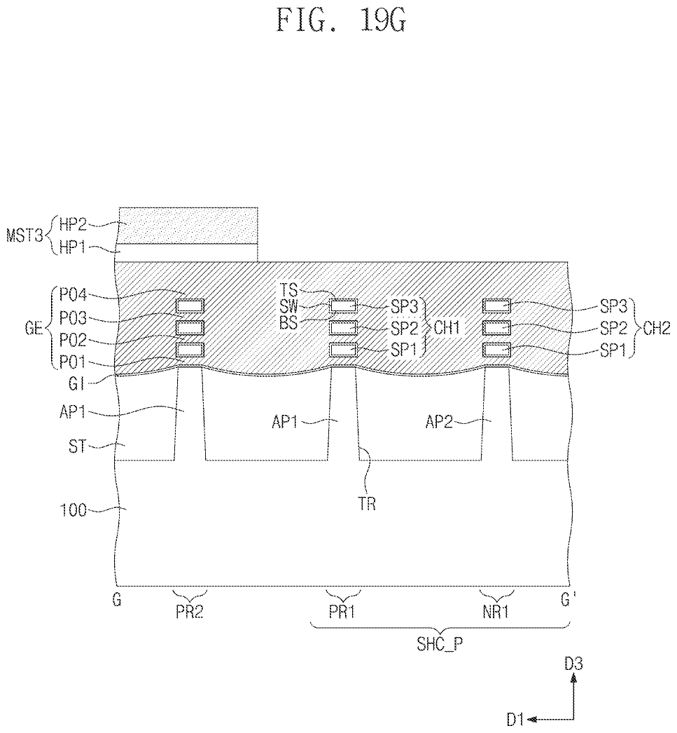

Referring to FIGS. 19A to 19G, a second etching process using the second mask structure MST2 of FIG. 18A as an etch mask may be performed on the first and second mask layers HMO1 and HMN1. The second etching process may be an anisotropic dry etching process. An etching gas or etchant material for the second etching process may be chosen to etch both the first and second mask layers HMO1 and HMN1. For example, the etching gas or etchant material may be chosen to etch silicon oxide and silicon nitride.

As a result of the second etching process, the first and second mask layers HMO1 and HMN1 may be formed to include a second etch recess region HM_RS2. The second etch recess region HM_RS2 may correspond to the opened region of the second mask structure MST2 described with reference to FIG. 18A). Referring to FIGS. 19A, 19B, 19C, 19E, 19F, and 19G, the second etch recess region HM_RS2 may be placed on the gate electrode GE of the first PMOSFET region PR1 and on the gate electrode GE of the first NMOSFET region NR1.

The first photolithography process, the first etching process, the second photolithography process, and the second etching process may be performed to form a third mask structure MST3. The third mask structure MST3 may include a first hard mask pattern HP1 and a second hard mask pattern HP2 on the first hard mask pattern HP1. Each of the first and second hard mask patterns HP1 and HP2 may include the first etch recess region HM_RS1 of FIG. 17D and the second etch recess region HM_RS2.

Referring back to FIGS. 5A to 5G, the isolation structure RIS may be formed. The formation of the isolation structure RIS may include performing a third etching process using the third mask structure MST3 of FIG. 19A as an etch mask and depositing the isolation structure RIS on a region that is recessed by the third etching process. In an implementation, the isolation structure RIS may be deposited by a chemical vapor deposition (CVD) process, a physical vapor deposition (PVD) process, or an atomic layer deposition (ALD) process.

In detail, the third etching process using the third mask structure MST3 of FIG. 19A as an etch mask may be performed on the gate electrode GE. The third etching process may be an anisotropic dry etching process (dry etch) process. An etchant material for the third etching process may be chosen to etch the gate electrode GE, the gate insulating layer GI, and the device isolation layer ST. For example, the etchant material may be chosen to etch a metallic material (e.g., tungsten (W)), which is included in the gate electrode GE, as well as silicon oxide.

In the fabrication method according to an implementation of the present disclosure, the etchant material may be chosen to etch the metallic material, silicon, and silicon oxide. In an implementation, the etchant material may exhibit different etch rates to the metallic material, the silicon, and the silicon oxide. For example, under the etchant material, an etch rate of the metallic material may be higher than an etch rate of the silicon. Under the etchant material, the etch rate of the silicon may be higher than an etch rate of the silicon oxide. Referring back to FIGS. 5F and 5G, due to the difference in etch selectivity under the etchant material, each of the second and third isolation patterns RIS_P2 and RIS_P3 may include the first and second portions, which are formed to have different vertical lengths from each other.

The third etching process may be optimized to form a region on the substrate 100, in which the isolation structure RIS will be formed, either simultaneously or as a single region. For example, an etchant material for the third etching process may be chosen to selectively etch the gate electrode GE and the semiconductor patterns SP1, SP2, and SP3, but not the first source/drain patterns SD1. This may be because the etchant material is chosen to etch metallic materials with a high etch rate, compared to the silicon-germanium (SiGe). Accordingly, it may be possible to reduce a loss of the first source/drain patterns SD1, which are adjacent to the second and third isolation patterns RIS_P2 and RIS_P3, and thereby to minimize a pattern defect. As a result, the semiconductor device fabricated by the fabrication method may have the improved electrical and reliability characteristics.

The deposited isolation structure RIS may include the first, second, and third isolation patterns RIS_P1, RIS_P2, and RIS_P3. The top surface of the first isolation pattern RIS_P1 may be substantially coplanar with the top surface of the gate electrode GE. The top surface of each of the second and third isolation patterns RIS_P2 and RIS_P3 may be substantially coplanar with the top surface of the first interlayer insulating layer 110 and the top surface of the gate spacer GS.

The second interlayer insulating layer 120 may be formed on the first interlayer insulating layer 110. The second interlayer insulating layer 120 may include a silicon oxide layer. The active contacts AC may be formed to penetrate the second and first interlayer insulating layers 120 and 110 and may be electrically connected to the first and second source/drain patterns SD1 and SD2. The gate contact GC may be formed to penetrate the second interlayer insulating layer 120 and may be electrically connected to the gate electrode GE.

In the case where, although not shown, the gate capping pattern is disposed on the gate electrode GE, a gate contact may be formed to penetrate the second interlayer insulating layer 120 and the gate capping pattern and may be electrically connected to the gate electrode GE.

The formation of each of the active and gate contacts AC and GC may include forming the barrier pattern BM and forming the conductive pattern FM on the barrier pattern BM. The barrier pattern BM may be conformally formed and may include a metal layer and/or a metal nitride layer. The conductive pattern FM may be formed of or include a low resistance metal.

Referring back to FIGS. 4 and 5A to 5G, the third interlayer insulating layer 130 may be formed on the active contacts AC and the gate contacts GC. The first metal layer M1 may be formed in the third interlayer insulating layer 130. The fourth interlayer insulating layer 140 may be formed on the third interlayer insulating layer 130. The second metal layer M2 may be formed in the fourth interlayer insulating layer 140.

The lower power lines VPR1 and VPR2 may be formed below the substrate 100. Each of the lower power lines VPR1 to VPR3 may be electrically connected to the active contact AC through an upper contact UCT. The power delivery network layer PDN may be formed on the bottom surface 100b of the substrate 100. The power delivery network layer PDN may be formed to apply the source or drain voltage to the lower power lines VPR1 and VPR2.

The formation of the lower power lines VPR1 and VPR2 may include performing a BEOL process on the substrate 100, inverting the substrate 100, performing a planarization process on the bottom surface 100b of the inverted substrate 100, forming an insulating layer 105 on the bottom surface 100b of the substrate 100, and performing a patterning process on the insulating layer 105. The patterning process may be, for example, a single damascene process or a dual damascene process.

In detail, the patterning process may include forming the barrier pattern BM and forming the conductive pattern FM on the barrier pattern BM. The barrier pattern BM may be conformally formed and may include a metal layer and/or a metal nitride layer. The conductive pattern FM may be formed of or include a low resistance metal.

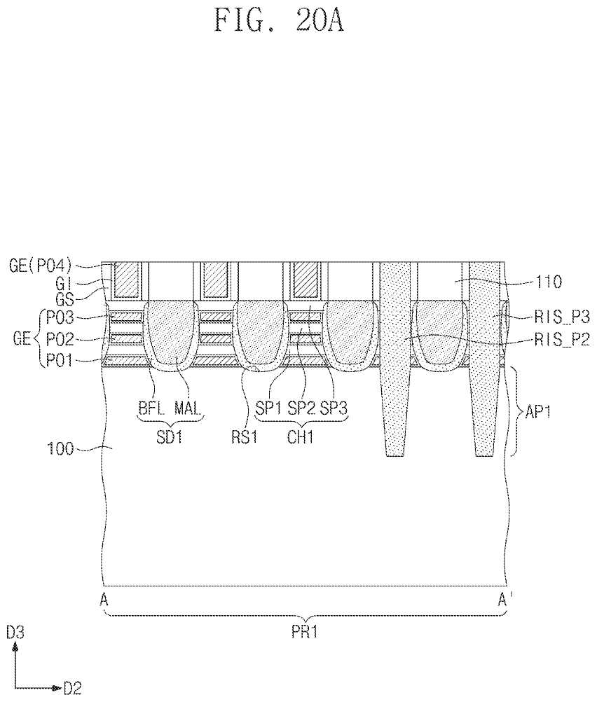

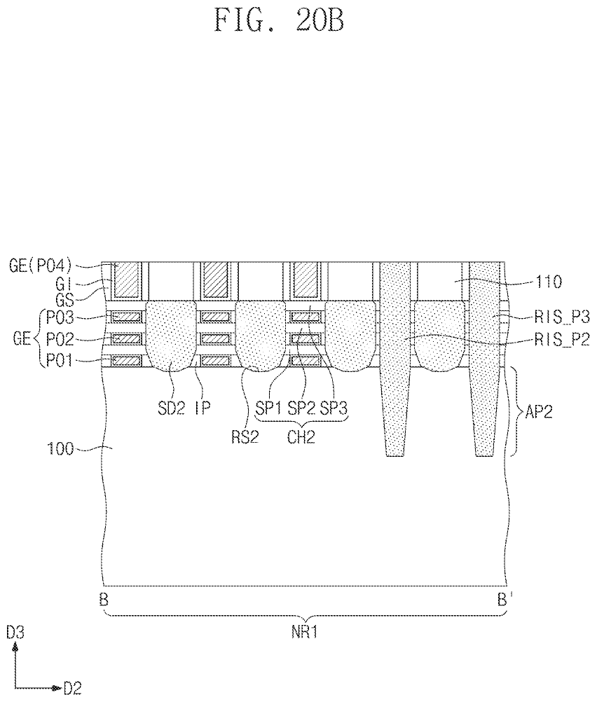

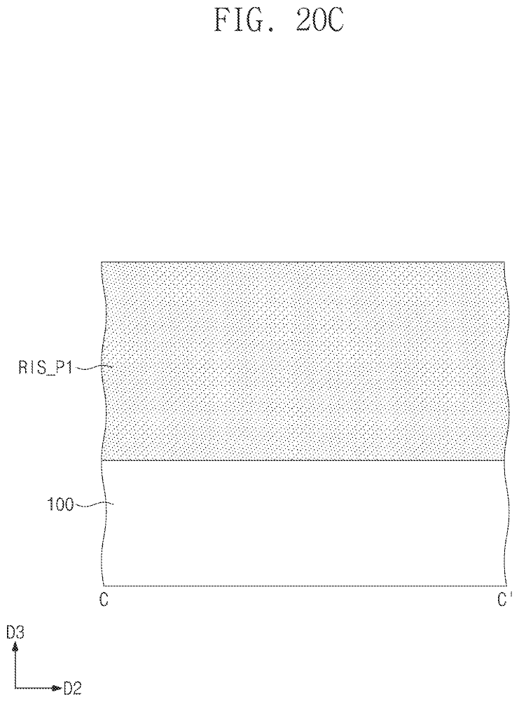

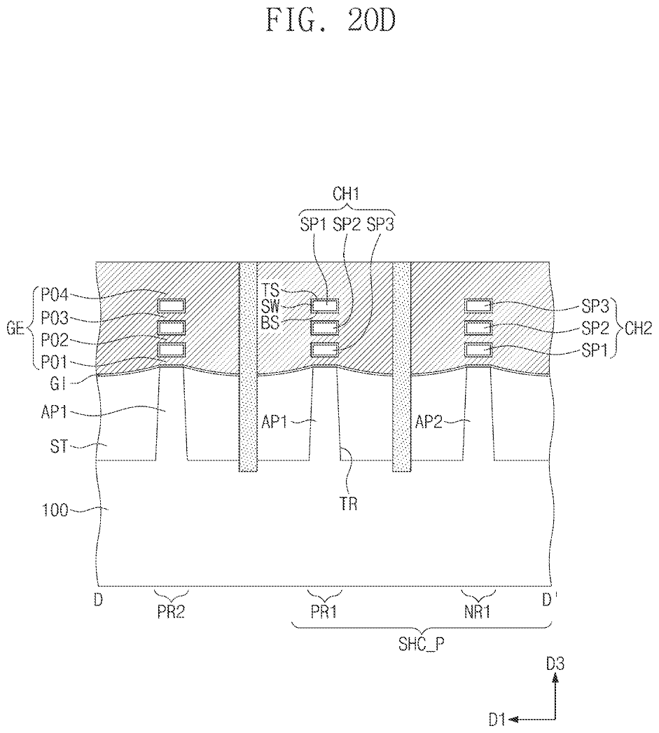

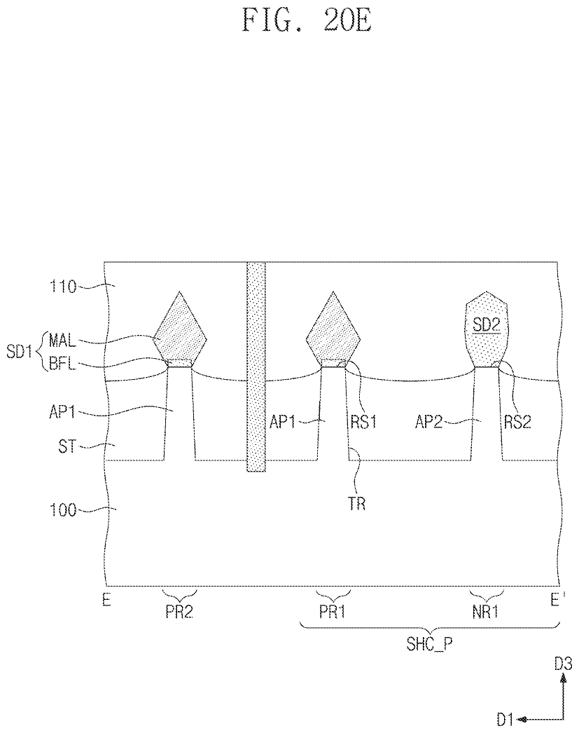

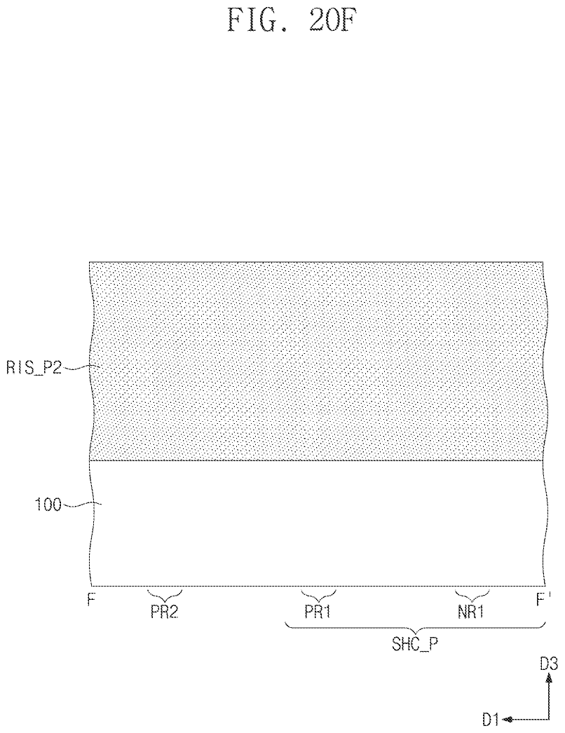

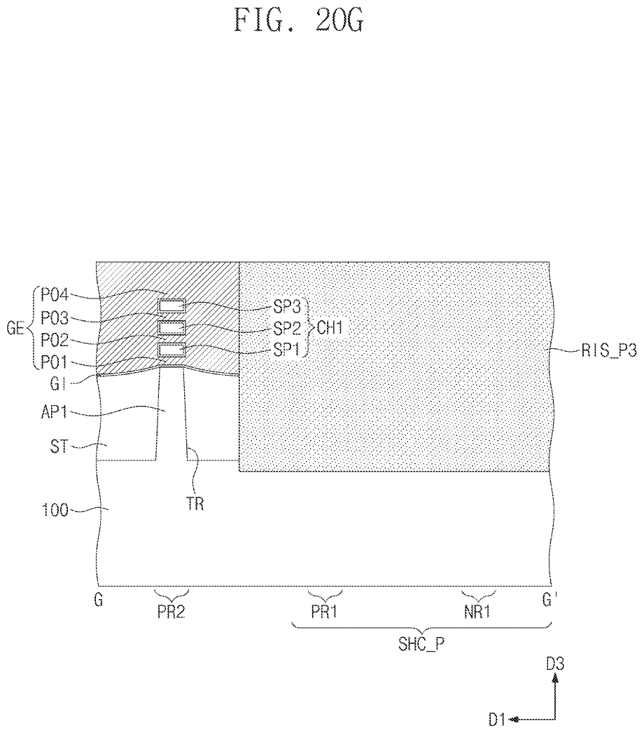

Hereinafter, a fabricating method according to another implementation of the present disclosure will be described. In the following description, an element previously described with reference to FIGS. 4 to 5G and 9A to 19G may be identified by the same reference number without repeating an overlapping description thereof, for concise description. FIGS. 20A to 20G are sectional views illustrating a semiconductor device, which is fabricated using another etchant material in a fourth etching process.

Referring to FIGS. 6A to 6C and FIGS. 20A to 20G, the isolation structure RIS may be formed such that the fourth height P1H′, the fifth height P2H′, and the sixth height P3H′ have the same value. The formation of the isolation structure RIS may include performing the fourth etching process using the third mask structure MST3 of FIG. 19A as an etch mask and depositing the isolation structure RIS on a region that is recessed by the fourth etching process.

In detail, the fourth etching process using the third mask structure MST3 of FIG. 19A as an etch mask may be performed on the gate electrode GE. The fourth etching process may be an anisotropic dry etching process.

The etchant material for the fourth etching process may be chosen to etch a metallic material, silicon, and silicon oxide. The etch rates of the metallic material, silicon, and silicon oxide under the etchant material may be similar or equal to each other. Thus, a depth of a recess region, in which the isolation structure RIS will be formed, may be controlled to a target depth. The target depth may be the fourth height P1H′, the fifth height P2H′, and the sixth height P3H′ described above. For example, the target depth may range from 140 nm to 180 nm. Referring back to FIGS. 6A to 6C, by adjusting the process time of the fourth etching process, the isolation structure RIS may be formed to have the same vertical distance.

The fourth etching process may be optimized to form a region on the substrate 100, in which the isolation structure RIS will be formed, either simultaneously or as a single region. For example, the etchant material for the fourth etching process may be chosen to etch the gate electrode GE and the semiconductor patterns SP1, SP2, and SP3, but not the first source/drain patterns SD1. Accordingly, it may be possible to reduce a loss of the first source/drain patterns SD1, which are adjacent to the second and third isolation patterns RIS_P2 and RIS_P3, and thereby to minimize a pattern defect. As a result, the semiconductor device fabricated by the fabrication method may have the improved electrical and reliability characteristics.

According to an implementation of the present disclosure, a three-dimensional field effect transistor may include a first isolation pattern, a second isolation pattern, and a third isolation pattern, which are formed at the same time or as a single object. Thus, the first, second, and third isolation patterns may be formed to have top surfaces, which are located at the same level, or have the same height, and in this case, it may be possible to reduce a cost for manufacturing a photomask. In addition, the first to third isolation patterns may be formed by an optimized etching process that may prevent loss of source/drain patterns adjacent thereto. Thus, it may be possible to efficiently fabricate the semiconductor device and prevent a defect from occurring in the source/drain patterns adjacent to the first to third isolation patterns. As a result, the electrical and reliability characteristics of the semiconductor device may be improved.

While example implementations of the present disclosure have been particularly shown and described, it will be understood by one of ordinary skill in the art that variations in form and detail may be made therein without departing from the spirit and scope of the attached claims.

What is claimed is:

1. A semiconductor device, comprising:
a substrate including an active pattern;
a device isolation layer defining the active pattern;
a channel pattern on the active pattern;
a gate electrode on the channel pattern; and
a first isolation pattern and a second isolation pattern that penetrate the gate electrode,
wherein the first isolation pattern extends into the device isolation layer,
wherein the second isolation pattern penetrates the gate electrode and the device isolation layer and extends into an upper portion of the substrate, and
wherein a level of a bottom surface of the second isolation pattern is lower than or equal to a level of a bottom surface of the device isolation layer.

2. The semiconductor device of claim 1, wherein the level of the bottom surface of the second isolation pattern is equal to the level of the bottom surface of the device isolation layer.

3. The semiconductor device of claim 1, wherein a level of a bottom surface of the first isolation pattern is higher than the level of the bottom surface of the device isolation layer.

4. The semiconductor device of claim 1, wherein the first isolation pattern and the second isolation pattern define a single object.

5. The semiconductor device of claim 1, wherein the first isolation pattern penetrates the device isolation layer and extends into an upper portion of the substrate, and
wherein the level of the bottom surface of the first isolation pattern is equal to the level of the bottom surface of the second isolation pattern.

6. The semiconductor device of claim 5, wherein a top surface of the first isolation pattern and a top surface of the second isolation pattern are located at a level that is equal to or higher than a top surface of the gate electrode, and
wherein the bottom surface of the first isolation pattern and the bottom surface of the second isolation pattern are located at a level lower than the bottom surface of the device isolation layer.

7. The semiconductor device of claim 1, wherein the second isolation pattern comprises:
a first portion extending into the device isolation layer; and
a second portion extending into an upper portion of the substrate, and
wherein a first depth of the first portion is smaller than a second depth of the second portion.

8. The semiconductor device of claim 7, wherein the second depth ranges from 140 nm to 180 nm.

9. The semiconductor device of claim 7, wherein the first depth of the first portion is equal to a first height of the first isolation pattern.

10. The semiconductor device of claim 1, wherein each of the first and second isolation patterns is a single layer including at least one of silicon oxide, silicon nitride, or silicon oxynitride.

11. The semiconductor device of claim 1, wherein each of the first and second isolation patterns defines a void adjacent to a top surface of each of the first and second isolation patterns.

12. The semiconductor device of claim 1, further comprising a gate capping pattern on the gate electrode,
wherein a top surface of the first isolation pattern and a top surface of the second isolation pattern are located at a level that is equal to or higher than a top surface of the gate capping pattern.

13. The semiconductor device of claim 1, wherein each of the first and second isolation patterns comprises a first sub-isolation pattern and a second sub-isolation pattern on the first sub-isolation pattern.

14. The semiconductor device of claim 13, wherein the first sub-isolation pattern comprises silicon nitride or silicon oxynitride, and
wherein the second sub-isolation pattern comprises silicon oxide.

15. The semiconductor device of claim 13, wherein the first and second isolation patterns define a void between the second sub-isolation pattern of the first isolation pattern and the second sub-isolation pattern of the second isolation pattern.

16. A semiconductor device, comprising:
a substrate;
a device isolation layer filling a trench on the substrate;
a first isolation pattern on the device isolation layer;
an active contact on the first isolation pattern; and
a lower power line provided below the substrate,
wherein the lower power line comprises an interconnection portion and a contact portion protruding from the interconnection portion toward the substrate, and
wherein the contact portion penetrates the substrate, the device isolation layer, and the first isolation pattern and is electrically connected to the active contact.

17. The semiconductor device of claim 16, wherein a width of the contact portion decreases as a distance from the interconnection portion increases in a direction toward the active contact.

18. A semiconductor device, comprising:
a first gate electrode, a second gate electrode, and a third gate electrode that are provided on a substrate, that extend in a first direction, and that are sequentially arranged in a second direction crossing the first direction;
source/drain patterns provided respectively between the first gate electrode, the second gate electrode, and the third gate electrode; and
an isolation structure penetrating the first gate electrode, the second gate electrode, and the third gate electrode,
wherein the isolation structure comprises:
a first isolation pattern extending in the second direction and dividing the first gate electrode into a pair of gate electrodes, the pair of gate electrode being spaced apart from each other in the first direction;
a second isolation pattern extending in the first direction and penetrating the second gate electrode;
a third isolation pattern extending in the first direction and penetrating the third gate electrode;
a first void on a first region where the first and second isolation patterns intersect each other; and
a second void on a second region where the first and third isolation patterns intersect each other,
wherein the first void includes a cross-shaped region having four curved surfaces, when viewed in a plan view of the semiconductor device, wherein the plan view faces a vertical direction orthogonal to the first direction and the second direction, and
wherein the second void is a T-shaped region having two curved surfaces, when viewed in the plan view of the semiconductor device.

19. The semiconductor device of claim 18, wherein the first, second, and third isolation patterns are formed simultaneously, and
wherein each of the first, second, and third isolation patterns comprises at least one of silicon oxide, silicon nitride, or silicon oxynitride.

20. The semiconductor device of claim 19, wherein each of the first, second, and third isolation patterns comprises a first sub-isolation pattern and a second sub-isolation pattern on the first sub-isolation pattern,
wherein the first sub-isolation pattern comprises silicon nitride or silicon oxynitride, and
wherein the second sub-isolation pattern comprises silicon oxide.
